(19) United States
(12) Patent Application Publication
(10) Pub. No.: US 2022/0009153 A1
(43) Pub. Date: Jan. 13, 2022

(54) COMPOSITION FOR FORMING PATTERN, KIT, CURED FILM, LAMINATE, PATTERN PRODUCING METHOD, AND METHOD FOR MANUFACTURING SEMICONDUCTOR ELEMENT

(71) Applicant: FUJIFILM Corporation, Tokyo (JP)

(72) Inventors: Yuichiro GOTO, Haibara-gun (JP); Naoya SHIMOJU, Haibara-gun (JP); Akinori SHIBUYA, Haibara-gun (JP); Akihiro HAKAMATA, Haibara-gun (JP)

(73) Assignee: FUJIFILM Corporation, Tokyo (JP)

(21) Appl. No.: 17/484,582

(22) Filed: Sep. 24, 2021

Related U.S. Application Data
(63) Continuation of application No. PCT/JP2020/012595, filed on Mar. 23, 2020.

(30) Foreign Application Priority Data
Mar. 29, 2019 (JP) 2019-068208

(51) Int. Cl. B29C 59/02; C08F 2/50; C08F 220/10; G03F 7/20; G03F 7/004

(52) U.S. Cl. CPC B29C 59/02; C08F 2/50; C08F 220/10; G03F 7/0046; G03F 7/2004; G03F 7/0045; G03F 7/2018

(57) ABSTRACT

Provided are: a composition for forming a pattern, which contains a polymerizable compound, a photopolymerization initiator, and a sensitizer containing two or more of at least one kind of atom selected from the group consisting of a nitrogen atom and a sulfur atom, in which a length of a specific atom chain from one atom to another atom among the two or more atoms is 2 or 3 in terms of the number of atoms; a kit to which the composition for forming a pattern is applied; a cured film; a laminate; a pattern producing method; and a method for manufacturing a semiconductor element.

### CROSS-REFERENCE TO RELATED APPLICATIONS

This application is a Continuation of PCT International Application No. PCT/JP2020/012595 filed on Mar. 23, 2020, which claims priority under 35 U.S.C § 119(a) to Japanese Patent Application No. 2019-068208 filed on Mar. 29, 2019. Each of the above application(s) is hereby expressly incorporated by reference, in its entirety, into the present application.

### BACKGROUND OF THE INVENTION

### 1. Field of the Invention

The present invention relates to a composition for forming a pattern, which is used in an imprinting method. Moreover, the present invention relates to a kit to which this composition is applied, a cured film, a laminate, a pattern producing method, and a method for manufacturing a semiconductor element.

### 2. Description of the Related Art

An imprinting method is a technique in which a fine pattern is transferred to a plastic material by pressing a metal mold (generally also called a mold or a stamper) on which a pattern is formed. The imprinting method enables simple and precise production of a fine pattern, and thus is expected to be applied in various fields in recent years. In particular, a nanoimprint technique for forming a fine pattern of a nano-order level is attracting attention.

The imprinting method is roughly classified into a thermal imprinting method and an optical imprinting method according to a transfer method thereof. In the thermal imprinting method, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. This method has an advantage that various materials can be selected, but also has problems in that a high pressure is required during pressing, and as the pattern size is finer, the dimensional accuracy is more likely to be reduced due to thermal shrinkage or the like. Meanwhile, in the optical imprinting method, after photocuring is performed in a state where a mold is pressed against a photocurable composition for forming a pattern, the mold is released. In this method, high-pressure application or high-temperature heating is not required, a dimensional change before and after curing is small, and thus there is an advantage that a fine pattern can be formed with high accuracy.

In the optical imprinting method, a composition for forming a pattern is applied onto a substrate, and then a mold made of a light-transmitting material such as quartz is pressed (JP2007-523249A). The composition for forming a pattern is cured by light irradiation in a state where the mold is pressed, and then the mold is released to produce a cured substance to which a desired pattern is transferred.

As irradiation light for curing the composition for forming a pattern, ultraviolet rays are usually used, and as a light source lamp which radiates the ultraviolet rays, a high-pressure mercury lamp, an ultra-high pressure mercury lamp, a low-pressure mercury lamp, a xenon lamp, a metal halide lamp, an excimer lamp, an ultraviolet ray light emitting diode (LED), and the like are used.

In addition, in order to ensure the reactivity to light, a photopolymerization initiator may be added to the composition for forming a pattern (JP2007-523249A, JP2015-070145A, and WO2016/152597A). As the photopolymerization initiator, a radical polymerization initiator, a cationic polymerization initiator, and the like are used, but from the viewpoint of a throughput (productivity), there is a tendency to select a radical polymerization initiator which has high reactivity and allows the curing reaction to proceed in a shorter time. Moreover, in order to further promote the reaction, the addition of a sensitizer and the like have also been under consideration (JP2008-238417A, JP2015-179807A, and JP2017-085148A).

### SUMMARY OF THE INVENTION

However, in the imprinting method using the composition for forming a pattern described in each of JP2008-238417A, JP2015-179807A, and JP2017-085148A, it was found that a polymerization reaction for forming a crosslinking structure did not sufficiently proceed in an exposure step, and pattern collapse defects may be generated due to insufficient pattern strength. For example, in a case where short-time exposure is performed in consideration of a throughput, such a problem is more likely to occur. The problem of such pattern collapse defects tends to make it difficult to transfer a fine pattern for high resolution, and remarkably appears, in particular, in an imprinting method such as transferring an ultrafine pattern of 20 nm or less.

The present invention has been made in consideration of the aforementioned problems, and an object of the present invention is to provide a composition for forming a pattern, which is capable of performing an imprinting method in which pattern collapse defects are suppressed. Moreover, another object of the present invention is to provide a kit to which the composition for forming a pattern is applied, a cured film, a laminate, a pattern producing method, and a method for manufacturing a semiconductor element.

The aforementioned problems can be solved by using a sensitizer, which exhibits an excellent sensitization action, in the composition for forming a pattern. Specifically, the aforementioned problems can be solved by the following unit <1> and preferably by a unit <2> and subsequent units.

<1>

A composition for forming a pattern for imprinting, comprising:

a polymerizable compound;

a photopolymerization initiator; and

a sensitizer containing two or more of at least one kind of atom selected from the group consisting of a nitrogen atom and a sulfur atom,

in which a length of a specific atom chain from one atom to another atom among the two or more atoms is 2 or 3 in terms of the number of atoms.

<2>

The composition for forming a pattern as described in <1>, in which the specific atom chain is included in a ring structure.

<3>

The composition for forming a pattern as described in <1> or <2>, in which the length of the specific atom chain is 3 in terms of the number of atoms.

<4>

The composition for forming a pattern as described in any one of <1> to <3>, in which a compound represented by Formula (PS-1) is contained as the sensitizer,

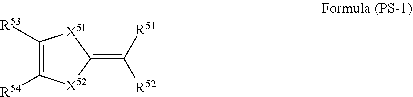

in Formula (PS-1),

X⁵¹ and X⁵² each independently represent —S— or —NR⁵⁵—, and R⁵⁵ represents a hydrogen atom or a monovalent substituent, and

R⁵¹ to R⁵⁴ each independently represent a hydrogen atom or a monovalent substituent, R⁵¹ and R⁵² may be bonded to each other to form a ring, and R⁵³ and R⁵⁴ may be bonded to each other to form a ring.

<5>

The composition for forming a pattern as described in <4>, in which at least one of R⁵¹, . . . , or R⁵⁴ has a π-conjugated linking group adjacent to a carbon atom to which at least one of R⁵¹, . . . , or R⁵⁴ is bonded.

<6>

The composition for forming a pattern as described in <5>, in which at least three of R⁵¹, . . . , or R⁵⁴ have a π-conjugated linking group adjacent to a carbon atom to which each of at least three of R⁵¹, . . . , or R⁵⁴ is bonded.

<7>

The composition for forming a pattern as described in <5> or <6>, in which the π-conjugated linking group is a linking group, which consists of one selected from the group consisting of —CR⁶⁰═CR⁶¹—, —CR⁶²═N—, —NR⁶³—, —O—, —C(═O)—, —S—, and —C(═S)—, or a combination of two or more thereof,

where R⁶⁰ to R⁶³ each independently represent a hydrogen atom or a monovalent substituent, and R⁶⁰ and R⁶′ may be bonded to each other to form a ring.

<8>

The composition for forming a pattern as described in any one of <1> to <7>, in which a compound represented by Formula (PS-2) is contained as the sensitizer,

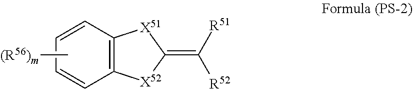

in Formula (PS-2),

X⁵¹ and X⁵² each independently represent —S— or —NR⁵⁵—, and R⁵⁵ represents a hydrogen atom or a monovalent substituent,

R⁵¹ and R⁵² each independently represent a hydrogen atom or a monovalent substituent, and may be bonded to each other to form a ring,

R⁵⁶ represents a monovalent substituent, and

m represents an integer of 0 to 4.

<9>

The composition for forming a pattern as described in <8>, in which a compound represented by Formula (PS-3) is contained as the sensitizer,

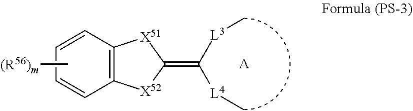

in Formula (PS-3),

X⁵¹, X⁵², R⁵⁶, and m have the same definitions as X⁵¹, X⁵², R⁵⁶, and m in Formula (PS-2), respectively,

L³ and L⁴ are each independently a divalent linking group, and at least one of L³ or L⁴ is a π-conjugated linking group, and

A represents a ring structure including L³ and L⁴.

<10>

The composition for forming a pattern as described in <9>, in which the entire ring structure A is a π-conjugated linking group which links two bonding sites of a carbon atom to which the ring structure A is bonded.

<11>

The composition for forming a pattern as described in <9> or <10>, in which the π-conjugated linking group in the ring structure A is a linking group, which consists of one selected from the group consisting of —CR⁶⁰═CR⁶¹—, —CR⁶²═N—, —NR⁶³—, —O—, —C(═O)—, —S—, and —C(═S)—, or a combination of two or more thereof,

where, in formulae, R⁶⁰ to R⁶³ each independently represent a hydrogen atom or a monovalent substituent, and R⁶⁰ and R⁶¹ may be bonded to each other to form a ring.

<12>

The composition for forming a pattern as described in <11>, in which the π-conjugated linking group in the ring structure A includes at least one of —NR⁶³— or —C(═O)—.

<13>

The composition for forming a pattern as described in any one of <9> to <12>, in which the ring structure A is a 5- to 7-membered ring.

<14>

The composition for forming a pattern as described in any one of <8> to <13>, in which a compound represented by Formula (PS-3a) or Formula (PS-3b) is contained as the sensitizer,

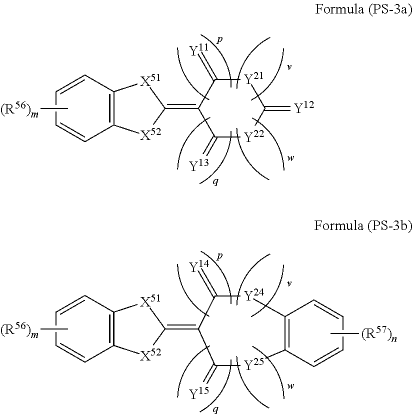

in Formula (PS-3a) and Formula (PS-3b),

X⁵¹, X⁵², R⁵⁶, and m have the same definitions as X⁵¹, X⁵², R⁵⁶, and m in Formula (PS-2), respectively,

Y¹¹, Y¹², Y¹³, Y¹⁴, and Y¹⁵ are each independently an oxygen atom or a sulfur atom,

Y²¹, Y²², Y²⁴, and Y²⁵ are each independently —CR⁷⁰R⁷¹—, —O—, —NR⁷²—, or —S—, and R⁷⁰ to R⁷² each represent a hydrogen atom or a monovalent substituent,

R⁵⁷ represents a monovalent substituent, and n represents an integer of 0 to 4,

p and q are each 0 or 1, and p+q satisfies 1 or 2,

v and w are each 0 or 1, and v+w satisfies 1 or 2, and

p+q+v+w in Formula (PS-3a) is 3 or 4, and p+q+v+w in Formula (PS-3b) is 2 or 3.

<15>

The composition for forming a pattern as described in any one of <4> to <14>, in which both X⁵¹ and X⁵² are —S−.

<16>

The composition for forming a pattern as described in any one of <4> to <14>, in which among X⁵¹ and X⁵², one is —NR⁵⁵— and the other is —S—.

<17>

The composition for forming a pattern as described in any one of <1> to <16>, in which a content of the sensitizer is 0.001% to 3% by mass with respect to an amount of a total solid content.

<18>

The composition for forming a pattern as described in any one of <1> to <17>, in which Cs/Ci, which is a mass ratio of a content Cs of the sensitizer to a content Ci of the photopolymerization initiator, is 0.0005 to 0.3.

<19>

The composition for forming a pattern as described in any one of <1> to <18>, in which at least one kind of an acylphosphine-based compound or an oxime ester-based compound is contained as the photopolymerization initiator.

<20>

The composition for forming a pattern as described in any one of <1> to <19>, in which the polymerizable compound includes a monofunctional polymerizable compound and a polyfunctional polymerizable compound, and a content of the monofunctional polymerizable compound in a total polymerizable compound is 5% to 30% by mass.

<21>

The composition for forming a pattern as described in any one of <1> to <20>, in which a viscosity of the composition for forming a pattern at 23° C. is 50 mPa·s or lower.

<22>

The composition for forming a pattern as described in any one of <1> to <21>, further comprising a release agent.

<23>

The composition for forming a pattern as described in any one of <1> to <22>, in which a solvent is not substantially contained.

<24>

A kit comprising a combination of the composition for forming a pattern as described in any one of <1> to <23> and a composition for forming an underlayer film, which is for forming an underlayer film for imprinting.

<25>

A cured film which is formed of the composition for forming a pattern as described in any one of <1> to <23>.

<26>

A laminate comprising:

a layered film consisting of the composition for forming a pattern as described in any one of <1> to <23>; and

a substrate supporting the layered film.

<27>

A pattern producing method comprising applying the composition for forming a pattern as described in any one of <1> to <23> onto a substrate or a mold and irradiating the composition for forming a pattern with light in a state of being sandwiched between the mold and the substrate.

<28>

A method for manufacturing a semiconductor element, comprising the producing method as described in <27> as a step.

<29>

The method for manufacturing a semiconductor element as described in <28>, further comprising etching the substrate using, as a mask, the pattern obtained by the producing method.

With the composition for forming a pattern according to an aspect of the present invention, an imprinting method, in which pattern collapse defects are suppressed, can be performed even in a case where short-time exposure to ultraviolet rays is performed in consideration of a throughput. Moreover, with the composition for forming a pattern according to the aspect of the present invention, it is possible to provide the kit, the cured film, the laminate, the pattern producing method, and the method for manufacturing a semiconductor element according to the aspect of the present invention.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step is achieved.

In the description of a group (atomic group) in the present specification, in a case where the group is described without specifying whether the group is substituted or unsubstituted, the description means that the group includes both a group having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group). Moreover, in a case where a group is simply described as an “alkyl group”, the description means that the alkyl group may be chain-like or cyclic, and may be linear or branched in a case where the alkyl group is chain-like.

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, “light” includes not only light having a wavelength in an ultraviolet, near-ultraviolet, far-ultraviolet, visible, or infrared range, or an electromagnetic wave but also a radiation. Examples of the radiation include microwaves, electron beams, extreme ultraviolet rays (EUV), and X-rays. Moreover, laser light such as a 248-nm excimer laser, a 193-nm excimer laser, and a 172-nm excimer laser can also be used. The light may be monochromatic light (single-wavelength light) passing through an optical filter, or may be light (composite light) having a plurality of wavelengths.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than the solvent, and a concentration of the solid content in the composition is represented by the mass percentage of the components other than the solvent with respect to the total mass of the composition, unless otherwise specified.

In the present specification, a temperature is 23° C. and an atmospheric pressure is 101,325 Pa (1 atm), unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 μm.

<Composition for Forming Pattern>

A composition for forming a pattern according to an embodiment of the present invention, which is used in an imprinting method, contains a polymerizable compound, a photopolymerization initiator, and a sensitizer containing two or more of at least one kind of atom (hereinafter, also referred to as a “specific atom”) selected from the group consisting of a nitrogen atom and a sulfur atom. Moreover, a length of a specific atom chain from one atom to another atom among the two or more atoms is 2 or 3 in terms of the number of atoms. Furthermore, two specific atoms extracted from the two or more atoms are included in the specific atom chain at a terminal thereof. That is, the expression “the length of the specific atom chain is 2” means that two specific atoms are adjacent to each other, and the expression “the length of the specific atom chain is 3” means that another atom is further present between two specific atoms.

In the present invention, in a case where the composition for forming a pattern contains the predetermined sensitizer, pattern collapse defects can be suppressed. The reason for that is not clear, but it is presumed that this is because the predetermined sensitizer efficiently absorbs light having a long-wavelength component, among light rays used for the exposure for curing the composition for forming a pattern, and the energy of the absorbed light contributes to the curing of the composition for forming a pattern. That is, it is considered that the energy of light, which has not been effectively utilized for curing the composition for forming a pattern in the related art, could be effectively utilized by using the predetermined sensitizer according to the present invention, and thus sufficient pattern strength can be obtained and the pattern collapse is suppressed. The present invention is effective, in particular, in that sufficient pattern strength can be obtained even in a case where short-time exposure is performed in consideration of a throughput.

Hereinafter, each component of the composition for forming a pattern according to the embodiment of the present invention will be described in detail.

<<Polymerizable Compound>>

The composition for forming a pattern according to the embodiment of the present invention contains a polymerizable compound having a polymerizable group. The polymerizable compound is preferably a radically polymerizable compound.

The polymerizable compound may be a monofunctional polymerizable compound having one polymerizable group, or a polyfunctional polymerizable compound having two or more polymerizable groups. The composition for forming a pattern according to the embodiment of the present invention preferably contains a polyfunctional polymerizable compound, and more preferably contains both a polyfunctional polymerizable compound and a monofunctional polymerizable compound. The polyfunctional polymerizable compound preferably includes at least one kind of a bifunctional polymerizable compound or a trifunctional polymerizable compound, and more preferably includes a bifunctional polymerizable compound.

Examples of the polymerizable group of the polymerizable compound include ethylenically unsaturated bond-containing groups such as a vinyl group, an allyl group, a vinylphenyl group, a (meth)acryloyl group, a (meth)acryloyloxy group, and a (meth)acryloylamino group. The polymerizable group is preferably a (meth)acryloyl group, a (meth)acryloyloxy group, and a (meth)acryloylamino group, and more preferably an acryloyl group, an acryloyloxy group, and an acryloylamino group.

A molecular weight of the polymerizable compound in the present invention is preferably less than 2,000, more preferably 1,500 or less, and still more preferably 1,000 or less, and may be 800 or less. The lower limit value thereof is preferably 100 or greater.

The polymerizable compound in the present invention may or may not contain a silicon atom. As such an embodiment, a case where the polymerizable compound is a polymerizable compound having a silicone skeleton is exemplified. Moreover, as another embodiment, a case where the polymerizable compound is a polymerizable compound containing no silicon atom is exemplified. Examples of the polymerizable compound having a silicone skeleton include SILICONE ACRYLATE X-22-1602 produced by Shin-Etsu Chemical Co., Ltd.

In the composition for forming a pattern according to the embodiment of the present invention, the polymerizable compound preferably includes both a monofunctional polymerizable compound and a polyfunctional polymerizable compound which has at least one of an alicyclic ring structure or an aromatic ring structure and has a viscosity at 23° C. of 150 mPa·s or lower. Moreover, a content of the monofunctional polymerizable compound in a total polymerizable compound contained in the composition is preferably 5% to 30% by mass. The upper limit of the content of the monofunctional polymerizable compound is preferably 25% by mass or less and more preferably 20% by mass or less. Furthermore, the lower limit of the content is preferably 8% by mass or greater and more preferably 10% by mass or greater. Consequently, a modulus of elasticity of a cured film formed of the composition for forming a pattern is 3.5 GPa or less, and a glass transition temperature (Tg) of the cured film is more likely to be 90° C. or higher. Here, the modulus of elasticity is a value obtained by measuring, by a microhardness tester, the cured film which is formed of the composition for forming a pattern and has a thickness of 20 μm. In this case, a triangular pyramid type having an inter-ridge angle of 115° is used as an indenter, and as measurement conditions, a test force is 10 mN, a loading rate is 0.142 mN/sec, a holding time is 5 seconds, and a temperature and a humidity during the measurement is 25° C. and 50%. As described above, by setting the modulus of elasticity of the cured film formed of the composition for forming a pattern to be equal to or less than a predetermined value, and setting the Tg of the cured film to be equal to or higher than a predetermined value, releasability is excellent, and the generation of waviness (ΔLWR) in an etching treatment can be further suppressed.

The composition for forming a pattern from which both a low modulus of elasticity and a high Tg of the cured film can be achieved can be more easily obtained by using a monofunctional polymerizable compound having a linear or branched hydrocarbon chain having 4 or more carbon atom. Specifically, as an aspect of the present invention, the polymerizable compound is preferably a combination of a monofunctional polymerizable compound, which has a linear or branched alkyl group having 8 or more carbon atoms and has a viscosity at 23° C. of 10 mPa·s or lower, and a polyfunctional polymerizable compound, which has at least one of an alicyclic ring structure or an aromatic ring structure and has a viscosity at 23° C. of 50 mPa·s or lower. In particular, in the combination, the polyfunctional polymerizable compound preferably includes at least one kind of a bifunctional polymerizable compound or a trifunctional polymerizable compound, and more preferably includes a bifunctional polymerizable compound. A content of the bifunctional polymerizable compound in a total polymerizable compound contained in the composition is preferably 70% to 95% by mass. The upper limit of the content of the bifunctional polymerizable compound is preferably 92% by mass or less and more preferably 90% by mass or less. Furthermore, the lower limit of the content is preferably 75% by mass or greater and more preferably 80% by mass or greater. Consequently, a modulus of elasticity of a cured film formed of the composition for forming a pattern is 3.5 GPa or less, and a glass transition temperature (Tg) of the cured film is more likely to be 90° C. or higher.

In the present invention, Cb/Ca, which is a mass ratio of a content Cb of the monofunctional polymerizable compound to a content Ca of the polyfunctional polymerizable compound, is preferably 10 to 50. The upper limit of the numerical range is more preferably 40 or less, still more preferably 30 or less, and particularly preferably 25 or less. Moreover, the lower limit of the numerical range is more preferably 12 or greater, still more preferably 14 or greater, and particularly preferably 15 or greater.

The modulus of elasticity of the cured film formed of the composition for forming a pattern according to the embodiment of the present invention is 3.5 GPa or less, preferably 3.1 GPa or less, more preferably 3.0 GPa or less, still more preferably 2.7 GPa or less, and even more preferably 2.5 GPa or less. The lower limit value of the modulus of elasticity is preferably 1.0 GPa or greater and more preferably 1.5 GPa or greater. By setting the modulus of elasticity within the above range, both the improvement in the releasability and the suppression of the pattern collapse can be further achieved.

The Tg of the cured film formed of the composition for forming a pattern according to the embodiment of the present invention is 90° C. or higher, more preferably 94° C. or higher, and still more preferably 100° C. or higher. The upper limit value of the Tg is not particularly specified. By setting the Tg within the above range, the aforementioned effects of the present invention can be further effectively exhibited, and pattern disconnection after etching can be further effectively suppressed.

A content of the polymerizable compound of the present invention is preferably 40% by mass or greater, more preferably 60% by mass or greater, still more preferably 70% by mass or greater, particularly preferably 80% by mass or greater, and even more preferably 90% by mass or greater, with respect to the entire composition for forming a pattern. Moreover, the content of the polymerizable compound of the present invention is preferably 99.9% by mass or less, more preferably 99% by mass or less, and still more preferably 98% by mass or less, with respect to the entire composition for forming a pattern.

The composition for forming a pattern according to the embodiment of the present invention may contain only one kind or two or more kinds of the polymerizable compounds. In a case where two or more kinds thereof are contained, the total amount thereof is preferably within the above range.

<<<Polyfunctional Polymerizable Compound>>>

The number of polymerizable groups of the polyfunctional polymerizable compound is 2 or more, preferably 2 to 7, more preferably 2 to 4, still more preferably 2 or 3, and even more preferably 2.

In the present invention, the polyfunctional polymerizable compound preferably includes a compound represented by Formula (2). By using such a polyfunctional polymerizable compound, adhesiveness, releasability, and temporal stability in the imprinting are well-balanced, and thus the composition for forming a pattern tends to be comprehensively superior.

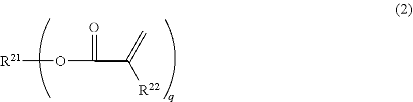

In the formula, R²¹ is a q-valent organic group, R²² is a hydrogen atom or a methyl group, and q is an integer of 2 or greater. q is preferably an integer of 2 to 7, more preferably an integer of 2 to 4, still more preferably 2 or 3, and even more preferably 2.

R²¹ is preferably a divalent to heptavalent organic group, more preferably a divalent to tetravalent organic group, still more preferably a divalent or trivalent organic group, and even more preferably a divalent organic group. R²¹ is preferably a hydrocarbon group having at least one of a linear structure, a branched structure, or a cyclic structure. The number of carbon atoms in the hydrocarbon group is preferably 2 to 20 and more preferably 2 to 10.

In a case where R²¹ is a divalent organic group, R²¹ is preferably an organic group represented by Formula (1-2).

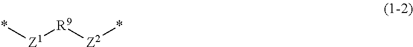

In the formula, it is preferable that Z¹ and Z² are each independently a single bond, —O—, -Alk-, or -Alk-O—. Alk represents an alkylene group (the number of carbon atoms is preferably 1 to 12, more preferably 1 to 6, and still more preferably 1 to 3), and may have a substituent as long as the effects of the present invention are not impaired. Examples of the substituent include the following substituents T. In the present specification, the asterisk in the chemical formula indicates a bonding site.

In the present specification, unless otherwise specified, examples of the substituent include one kind of substituent T selected from a halogen atom, a cyano group, a nitro group, a hydrocarbon group, a heterocyclic group, —ORt¹, —CORt¹, —COORt¹, —OCORt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, or —SO₂NRt¹Rt². Here, Rt¹ and Rt² each independently represent a hydrogen atom, a hydrocarbon group, or a heterocyclic group. In a case where Rt¹ and Rt² are hydrocarbon groups, Rt¹ and Rt² may be bonded to each other to form a ring.

Regarding the substituent T, examples of the halogen atom include a fluorine atom, a chlorine atom, a bromine atom, and an iodine atom. Examples of the hydrocarbon group include an alkyl group, an alkenyl group, an alkynyl group, and an aryl group. The number of carbon atoms in the alkyl group is preferably 1 to 10, more preferably 1 to 5, and still more preferably 1 or 2. The alkyl group may be linear, branched, or cyclic, and is preferably linear or branched. The number of carbon atoms in the alkenyl group is preferably 2 to 10, more preferably 2 to 5, and particularly preferably 2 or 3. The alkenyl group may be linear, branched, or cyclic, and is preferably linear or branched. The number of carbon atoms in the alkynyl group is preferably 2 to 10 and more preferably 2 to 5. The alkynyl group may be linear or branched, and is preferably linear. The number of carbon atoms in the aryl group is preferably 6 to 10, more preferably 6 to 8, and still more preferably 6 or 7. The heterocyclic group may be a single ring or a polycyclic ring. The heterocyclic group is preferably a single ring or a polycyclic ring having 2 to 4 rings. The number of heteroatoms constituting the ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 10, more preferably 3 to 8, and still more preferably 3 to 5.

The hydrocarbon group and the heterocyclic group as the substituent T may further have another substituent or may be unsubstituted. Examples of the other substituent here include the aforementioned substituents T.

R⁹ is a single bond or a divalent linking group. The linking group is preferably a linking group selected from Formulae (9-1) to (9-10), or a combination thereof. Among them, a linking group selected from Formulae (9-1) to (9-3), (9-7), and (9-8) is preferable.

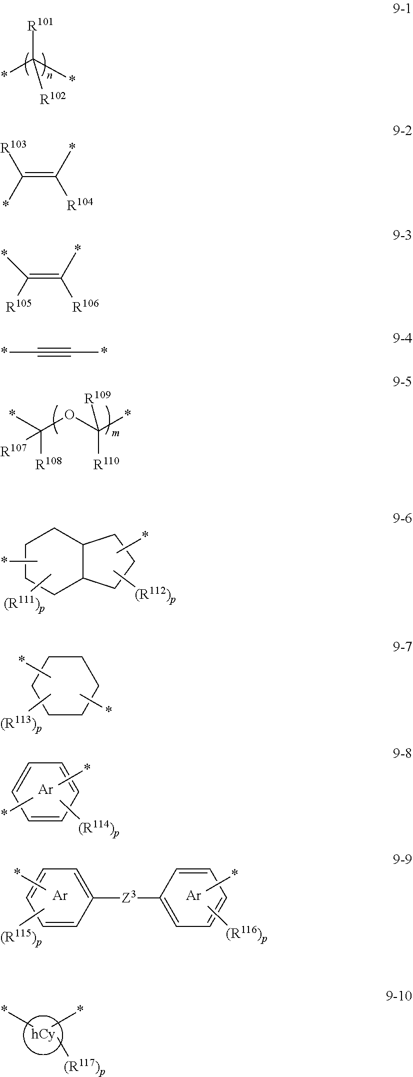

R¹⁰¹ to R¹¹⁷ are optional substituents. Among them, an alkyl group (the number of carbon atoms is preferably 1 to 12, more preferably 1 to 6, and still more preferably 1 to 3), an arylalkyl group (the number of carbon atoms is preferably 7 to 21, more preferably 7 to 15, and still more preferably 7 to 11), an aryl group (the number of carbon atoms is preferably 6 to 22, more preferably 6 to 18, and still more preferably 6 to 10), a thienyl group, a furyl group, a (meth)acryloyl group, a (meth)acryloyloxy group, and a (meth)acryloyloxyalkyl group (the number of carbon atoms in the alkyl group is preferably 1 to 24, more preferably 1 to 12, and still more preferably 1 to 6) are preferable. R¹⁰¹ and R¹⁰², R¹⁰³ and R¹⁰⁴, R¹⁰⁵ and R¹⁰⁶, R¹⁰⁷ and R¹⁰⁸, R¹⁰⁹ and R¹¹⁰, a plurality of R¹¹¹'s, a plurality of R¹¹²'s, a plurality of R¹¹³'s, a plurality of R¹¹⁴'s, a plurality of R¹¹⁵'s, a plurality of R¹¹⁶'s, and a plurality of R¹¹⁷'s may be respectively bonded to each other to form a ring.

Ar is an arylene group (the number of carbon atoms is preferably 6 to 22, more preferably 6 to 18, and still more preferably 6 to 10), and specific examples thereof include a phenylene group, a naphthalenediyl group, an anthracenediyl group, a phenanthrenediyl group, and a fluorenediyl group.

hCy is a heterocyclic group (the number of carbon atoms is preferably 1 to 12, more preferably 1 to 6, and still more preferably 2 to 5), and is more preferably a 5-membered ring or a 6-membered ring. Specific examples of a hetero ring constituting hCy include a thiophene ring, a furan ring, a dibenzofuran ring, a carbazole ring, an indole ring, a tetrahydropyran ring, a tetrahydrofuran ring, a pyrrole ring, a pyridine ring, a pyrazole ring, an imidazole ring, a benzimidazole ring, a triazole ring, a thiazole ring, an oxazole ring, a pyrrolidone ring, and a morpholine ring, and among them, a thiophene ring, a furan ring, and a dibenzofuran ring are preferable.

Z³ is a single bond or a linking group. Examples of the linking group include alkylene groups (the number of carbon atoms is preferably 1 to 12, more preferably 1 to 6, and still more preferably 1 to 3) in which an oxygen atom, a sulfur atom, and a fluorine atom may be substituted.

n and m are each a natural number of 100 or less, and are each preferably 1 to 12, more preferably 1 to 6, and still more preferably 1 to 3.

p is 0 or greater and is an integer equal to or less than the maximum number of groups which can be substituted for each ring. In the respective cases, the upper limit values are independently preferably equal to or less than half of the maximum number of the substitutable group, more preferably 4 or less, and still more preferably 2 or less.

The polyfunctional polymerizable compound is preferably represented by Formula (2-1).

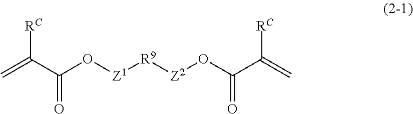

In Formula (2-1), R^{C} is a hydrogen atom or a methyl group. Moreover, R⁹, Z¹, and Z² have the same definitions as R⁹, Z¹, and Z² in Formula (1-2), respectively, and preferred ranges thereof are also the same.

A kind of an atom constituting the polyfunctional polymerizable compound used in the present invention is not particularly specified, but the polyfunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

Examples of the polyfunctional polymerizable compound preferably used in the present invention include the following compounds. Moreover, the examples include the polymerizable compound described in JP2014-170949A, the contents of which are incorporated in the present specification.

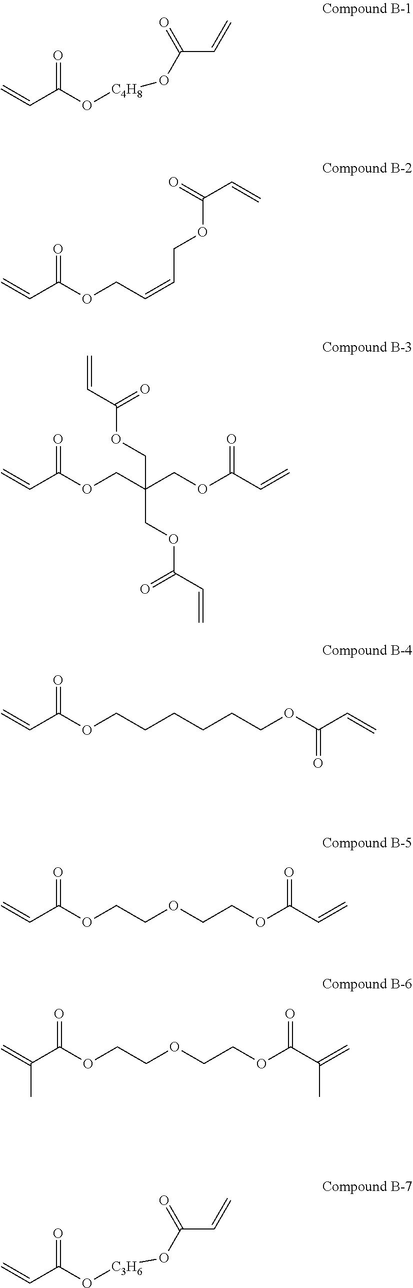

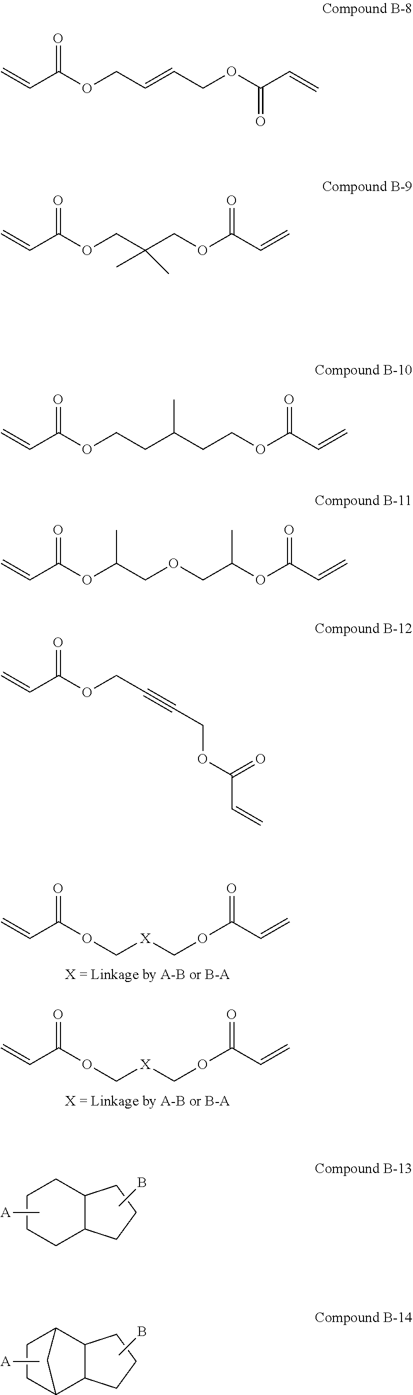

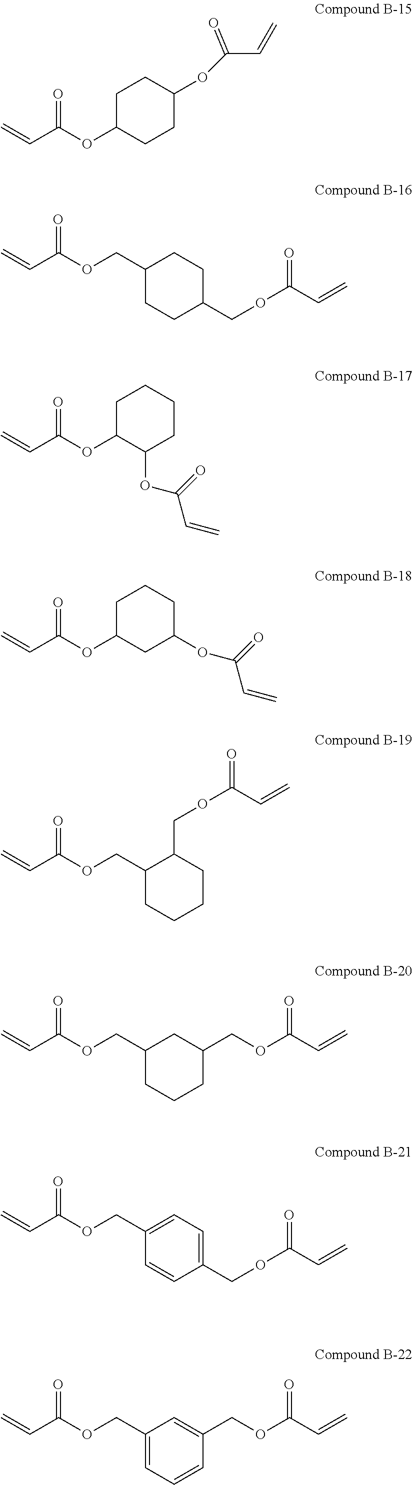

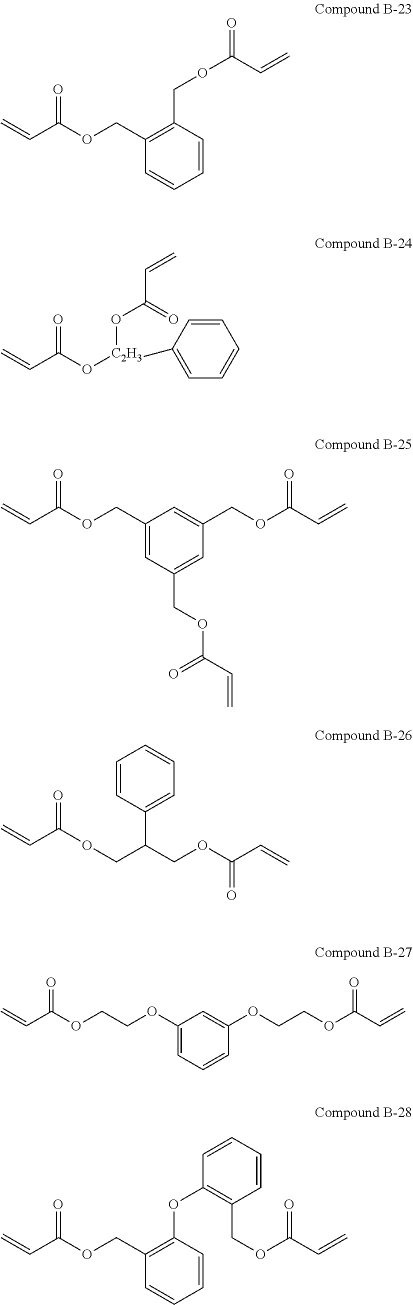

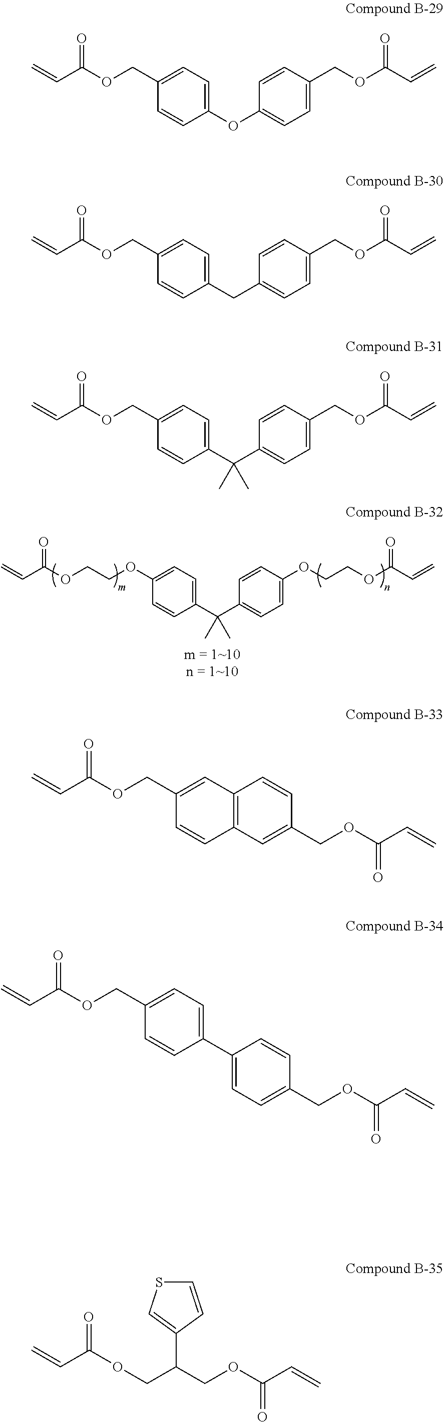

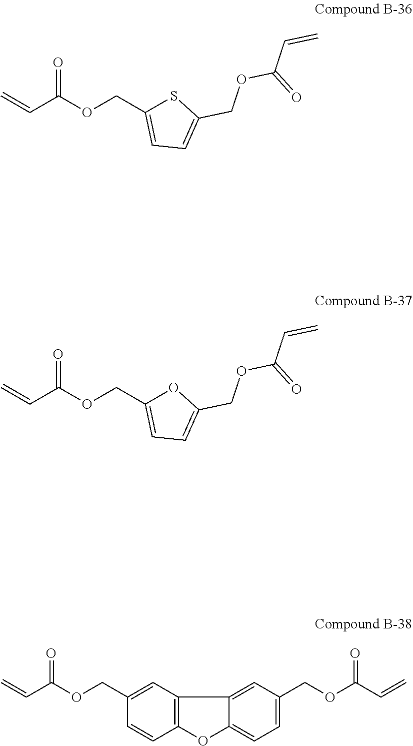

The content of the polyfunctional polymerizable compound used in the present invention is preferably 30% to 99% by mass, more preferably 50% to 95% by mass, and still more preferably 75% to 90% by mass, and may be 80% to 90% by mass, with respect to the total polymerizable compound in the composition. The composition for forming a pattern may contain only one kind or two or more kinds of the polyfunctional polymerizable compounds. In a case where two or more kinds thereof are contained, the total amount thereof is preferably within the above range.

The composition for forming a pattern according to the embodiment of the present invention may contain a polyfunctional oligomer having a higher molecular weight than the polyfunctional polymerizable compound. Consequently, the crosslink density can be further increased. Examples of a polyfunctional oligomer having photoradical polymerizability include various acrylate oligomers such as polyester acrylate, urethane acrylate, polyether acrylate, and epoxy acrylate. An addition amount of the oligomer component is preferably 0% to 30% by mass, more preferably 0% to 20% by mass, still more preferably 0% to 10% by mass, and most preferably 0% to 5% by mass, with respect to an amount of a total solid content in the composition for forming a pattern.

<<<Monofunctional Polymerizable Compound>>>

As described above, it is preferable that the monofunctional polymerizable compound, which can be used in the present invention, has a cyclic structure, or a linear or branched hydrocarbon chain having 4 or more carbon atoms. In the present invention, only one kind or two or more kinds of the monofunctional polymerizable compounds may be contained.

The monofunctional polymerizable compound used in the present invention is preferably a liquid at 23° C. In the present invention, the compound which is a liquid at 23° C. means a compound having fluidity at 23° C., for example, a compound having a viscosity at 23° C. of 1 to 100,000 mPa·s. The viscosity of the monofunctional polymerizable compound at 23° C. is, for example, more preferably 10 to 20,000 mPa·s and still more preferably 100 to 15,000 mPa·s.

By using the compound which is a liquid at 23° C., a configuration in which the composition for forming a pattern does not substantially contain a solvent can be adopted. Here, the expression “not substantially contain a solvent” means, for example, that the content of the solvent in the composition for forming a pattern according to the embodiment of the present invention is 5% by mass or less. The content of the solvent in the composition for forming a pattern is preferably 3% by mass or less and more preferably 1% by mass or less.

The viscosity of the monofunctional polymerizable compound used in the present invention at 23° C. is preferably 100 mPa·s or lower, more preferably 10 mPa·s or lower, still more preferably 8 mPa·s or lower, and even more preferably 6 mPa·s or lower. By setting the viscosity of the monofunctional polymerizable compound at 23° C. to be equal to or lower than the upper limit value, the viscosity of the composition for forming a pattern can be reduced, and thus filling properties tend to be improved. The lower limit value thereof is not particularly specified, but can be, for example, 1 mPa·s or higher.

The monofunctional polymerizable compound used in the present invention is preferably a monofunctional (meth)acrylic monomer and more preferably monofunctional acrylate.

A kind of an atom constituting the monofunctional polymerizable compound used in the present invention is not particularly specified, but the monofunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

The monofunctional polymerizable compound used in the present invention preferably has a plastic structure. For example, it is preferable that at least one kind of the monofunctional polymerizable compounds used in the present invention contains one group selected from the group consisting of the following (1) to (3).

(1) A group (hereinafter, referred to as a “group (1)” in some cases) which has at least one of an alkyl chain or an alkenyl chain and at least one of an alicyclic ring structure or an aromatic ring structure, and has the total number of carbon atoms of 7 or more

(2) A group (hereinafter, referred to as a “group (2)” in some cases) containing an alkyl chain having 4 or more carbon atoms

(3) A group (hereinafter, referred to as a “group (3)” in some cases) containing an alkenyl chain having 4 or more carbon atoms

With such a configuration, a modulus of elasticity of a cured film can be efficiently reduced while reducing the addition amount of the monofunctional polymerizable compound contained in the composition for forming a pattern. Moreover, interfacial energy with the mold is reduced, and thus an effect of reducing a releasing force (effect of improving releasability) can be enhanced.

In the groups (1) to (3), the alkyl chain and the alkenyl chain may be linear, branched, or cyclic, and are each independently preferably linear or branched. Moreover, it is preferable that the groups (1) to (3) have the alkyl chain and/or the alkenyl chain at a terminal of the monofunctional polymerizable compound, that is, have an alkyl group and/or an alkenyl group. With such a structure, the releasability can be further improved.

The alkyl chain and the alkenyl chain may each independently contain an ether group (—O—), but it is preferable that an ether group is not contained from the viewpoint of improvement in the releasability.

Group (1)

The total number of carbon atoms in the group (1) is preferably 35 or less and more preferably 10 or less.

As the cyclic structure, a single ring or a polycyclic ring of 3- to 8-membered rings is preferable. The number of rings constituting the polycyclic ring is preferably 2 or 3. The cyclic structure is more preferably a 5-membered ring or a 6-membered ring and still more preferably a 6-membered ring. Moreover, a single ring is more preferable. As the cyclic structure in the group (1), a cyclohexane ring, a benzene ring, and a naphthalene ring are more preferable, and a benzene ring is particularly preferable. Moreover, the cyclic structure is preferably an aromatic ring structure.

The number of cyclic structures in the group (1) may be 1 or may be 2 or more, but is preferably 1 or 2 and more preferably 1. Furthermore, in a case of a polycyclic ring, the fused ring is considered as one cyclic structure.

Group (2)

The group (2) is a group containing an alkyl chain having 4 or more carbon atoms, and preferably a group (that is, an alkyl group) consisting of an alkyl chain having 4 or more carbon atoms. The number of carbon atoms in the alkyl chain is preferably 7 or more and more preferably 9 or more. The upper limit value of the number of carbon atoms in the alkyl chain is not particularly limited, but can be, for example, 25 or less. Moreover, a compound in which some carbon atoms of the alkyl chain are substituted with silicon atoms can also be exemplified as the monofunctional polymerizable compound.

Group (3)

The group (3) is a group containing an alkenyl chain having 4 or more carbon atoms, and preferably a group (that is, an alkylene group) consisting of an alkenyl chain having 4 or more carbon atoms. The number of carbon atoms in the alkenyl chain is preferably 7 or more and more preferably 9 or more. The upper limit value of the number of carbon atoms in the alkenyl chain is not particularly limited, but can be, for example, 25 or less.

The monofunctional polymerizable compound used in the present invention is preferably a compound in which any one or more of the group (1), . . . , or (3) are bonded to a polymerizable group directly or via a linking group, and more preferably a compound in which any one of the group (1), . . . , or (3) is directly bonded to a polymerizable group. Examples of the linking group include —O—, —C(═O)—, —CH₂—, —NH—, or a combination thereof.

Specific examples of the monofunctional polymerizable compound are as follows. However, in the present invention, the monofunctional polymerizable compound is not limited to the following compounds.

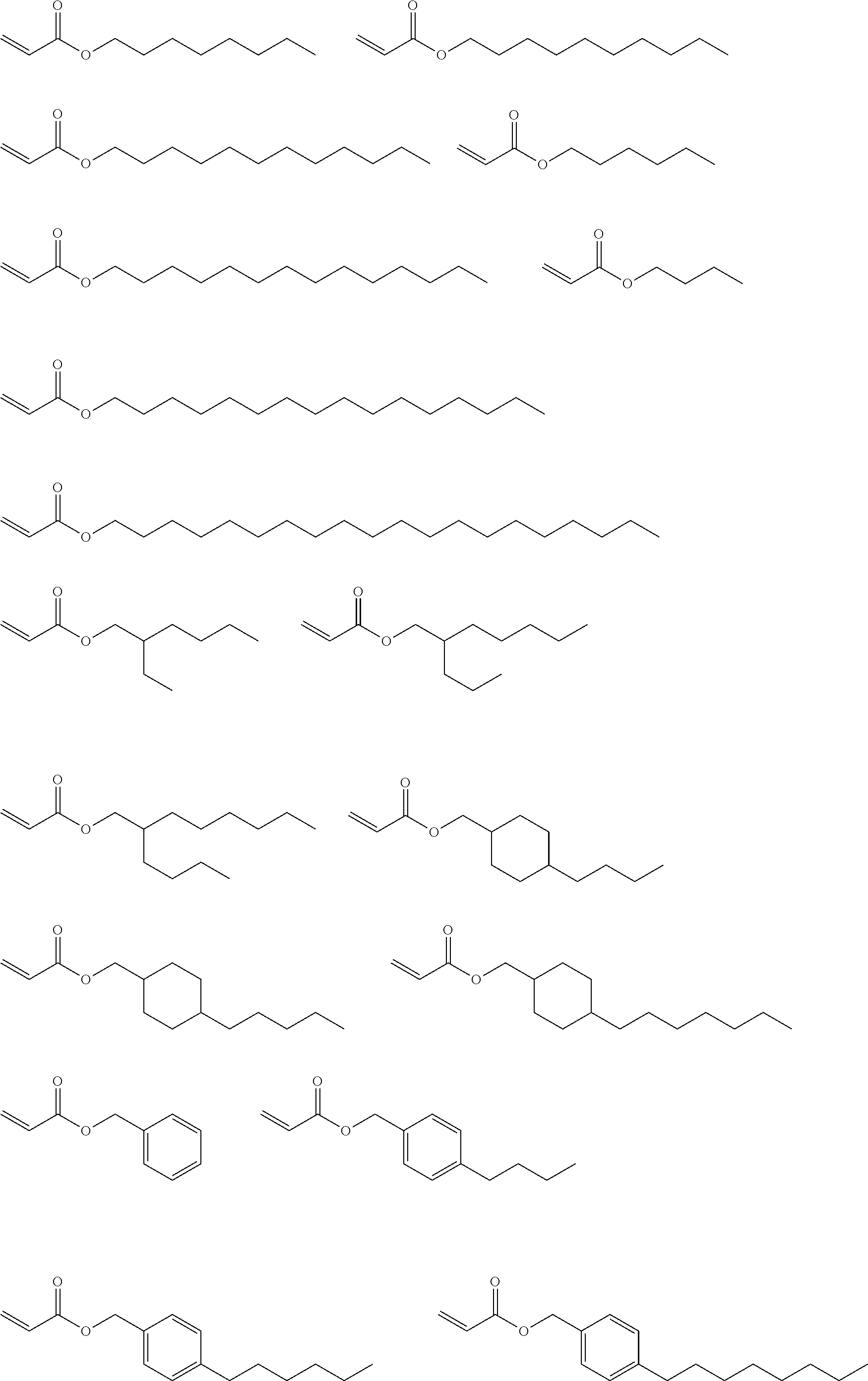

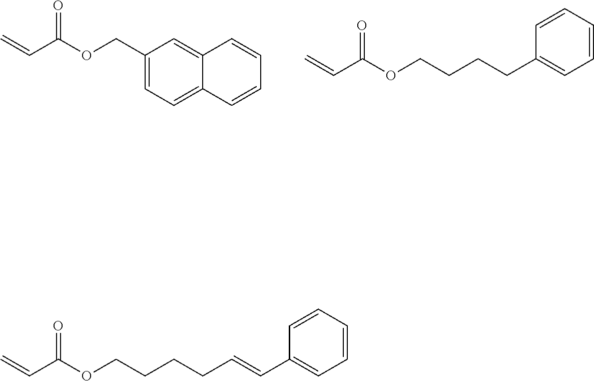

The lower limit value of an amount of the monofunctional polymerizable compound with respect to the total polymerizable compound in the composition for forming a pattern is preferably 1% by mass or greater, more preferably 3% by mass or greater, still more preferably 5% by mass or greater, and even more preferably 7% by mass or greater. Moreover, the upper limit value thereof is more preferably 29% by mass or less, still more preferably 27% by mass or less, even more preferably 25% by mass or less, further still more preferably 20% by mass or less, and further still more preferably 15% by mass or less. By setting the amount of the monofunctional polymerizable compound with respect to the total polymerizable compound to be equal to or greater than the lower limit value, the releasability can be improved, and thus defects in a pattern or damage to the mold can be suppressed in a case of releasing the mold. Furthermore, by setting the amount to be equal to or less than the upper limit value, the Tg of the cured film formed of the composition for forming a pattern can be increased, and thus resistance to etching processing, in particular, waviness of a pattern during etching can be suppressed.

In the present invention, monofunctional polymerizable compounds other than the aforementioned monofunctional polymerizable compounds may be used as long as the compounds do not depart from the spirit of the present invention, and examples thereof include the monofunctional polymerizable compounds among the polymerizable compounds described in JP2014-170949A, the contents of which are incorporated in the present specification.

<<Photopolymerization Initiator>>

The composition for forming a pattern according to the embodiment of the present invention contains a photopolymerization initiator. Moreover, the photopolymerization initiator is preferably a photoradical polymerization initiator. As the photopolymerization initiator used in the present invention, any compound can be used as long as the compound generates an active species, which polymerizes the aforementioned polymerizable compounds, by light irradiation. Specific examples of the compound for the photopolymerization initiator include the compounds described in paragraph 0091 of JP2008-105414A.

In the composition for forming a pattern according to the embodiment of the present invention, from the viewpoints of curing sensitivity and absorption characteristics, for example, the photopolymerization initiator preferably includes at least one kind of an acetophenone-based compound (compound having an acetophenone skeleton), an acylphosphine oxide-based compound (compound having an acylphosphine oxide skeleton), or an oxime ester-based compound (compound having an oxime ester skeleton), more preferably includes at least one kind of an acylphosphine oxide-based compound or an oxime ester-based compound, and still more preferably includes an acylphosphine oxide-based compound.

As the photopolymerization initiator, commercially available initiators can also be used. Examples of such initiators include DAROCUR (registered trademark) 1173 (produced by Ciba Specialty Chemicals Inc.), Irgacure (registered trademark) OXE01, Irgacure OXE02, Irgacure OXE04, Irgacure TPO, Irgacure TPO-L, Irgacure 127, Irgacure 184, Irgacure 369, Irgacure 369E, Irgacure 379EG, Irgacure 651, Irgacure 754, Irgacure 819, Irgacure 907, Irgacure 1173, Irgacure 1800, and Irgacure 2959 (all produced by BASF SE), and Omnirad (registered trademark) TPO-H, Omnirad TPO-L, Omnirad 127, Omnirad 184, Omnirad 369, Omnirad 369E, Omnirad 379EG, Omnirad 651, Omnirad 754, Omnirad 819, Omnirad 907, Omnirad 1173, and Omnirad 2959 (all produced by IGM Resins B.V.).

In the present invention, an oxime compound having a fluorine atom can also be used as the photopolymerization initiator. Specific examples of the oxime compound having a fluorine atom include the compound described in JP2010-262028A, the compounds 24 and 36 to 40 described in JP2014-500852A, and the compound (C-3) described in JP2013-164471A. The contents thereof are incorporated in the present specification.

The photopolymerization initiator may be used alone, but it is also preferable to use two or more kinds thereof in combination. By combining a plurality of photopolymerization initiators, an exposure margin can be expanded. Specifically, it is preferable to use two or more kinds among the three kinds of photopolymerization initiators in combination, and in particular, a combination of an acylphosphine oxide-based compound and an acetophenone-based compound, or a combination of an oxime ester-based compound and an acetophenone-based compound is preferable, and a combination of an acylphosphine oxide-based compound and an acetophenone-based compound is more preferable. In a case where the acylphosphine oxide-based compound is combined with the acetophenone-based compound, Cf/Cp, which is a mass ratio of a content Cf of the acetophenone-based compound to a content Cp of the acylphosphine oxide-based compound, is preferably 0.2 to 2.0. The upper limit of the numerical range is preferably 1.5 or less, more preferably 1.2 or less, and still more preferably 1.0 or less. Moreover, the lower limit of the numerical range is preferably 0.3 or greater, more preferably 0.5 or greater, and still more preferably 0.6 or greater.

In addition, as the photopolymerization initiator, for example, a combination of commercially available initiators can also be used. Specific examples thereof include respective combinations of Omnirad 1173 and Omnirad 907, Omnirad 1173 and Omnirad TPO (H or L), Omnirad 1173 and Omnirad 819, Omnirad 1173 and Irgacure OXE01, Omnirad 907 and Omnirad TPO (H or L), and Omnirad 907 and Omnirad 819. By using such a combination, an exposure margin can be expanded.

A maximum light absorption coefficient of the photopolymerization initiator at a wavelength of 300 to 500 nm is preferably 0.1 to 1,000 L/(g·cm). The upper limit of the numerical range is preferably 1,000 L/(g·cm) or less, more preferably 500 L/(g·cm) or less, and still more preferably 100 L/(g·cm) or less. Moreover, the lower limit of the numerical range is preferably 0.1 L/(g·cm) or greater, more preferably 1.0 L/(g·cm) or greater, and still more preferably 10 L/(g·cm) or greater.

In the composition for forming a pattern according to the embodiment of the present invention, the content of the total photopolymerization initiator is preferably 0.01% to 10% by mass with respect to the amount of the total solid content in the composition for forming a pattern. The upper limit of the numerical range is preferably 7.0% by mass or less, more preferably 5.5% by mass or less, and still more preferably 4.5% by mass or less. Moreover, the lower limit of the numerical range is preferably 0.1% by mass or greater, more preferably 0.5% by mass or greater, and still more preferably 1.0% by mass or greater. The photopolymerization initiator may be used alone or in combination of two or more kinds thereof. In a case where two or more kinds of the photopolymerization initiators are contained, the total amount thereof is preferably within the above range.

<<Sensitizer>>

In the composition for forming a pattern according to the embodiment of the present invention, the sensitizer contains two or more of at least one kind of atom selected from the group consisting of a nitrogen atom and a sulfur atom. A length of a specific atom chain from one specific atom to another specific atom among the two or more specific atoms is 2 or 3 in terms of the number of atoms, and is preferably 3 from the viewpoint that pattern collapse defects are suppressed. It is not clear why the collapse defects are further suppressed by setting the length of the specific atom chain to 3, but it is considered that this is because a short distance between the specific atoms present at respective terminals of the specific atom chain causes the state of electrons belonging to the specific atom chain to be suitable for absorption of light, or energy transfer from a sensitizer to a photopolymerization initiator.

A molecular weight of the sensitizer in the present invention is preferably less than 2,000, more preferably 1,000 or less, still more preferably 800 or less, even more preferably 600 or less, and particularly preferably 550 or less, and may be 500 or less. The lower limit value thereof is preferably 100 or greater, more preferably 200 or greater, and still more preferably 250 or greater.

In the sensitizer, the number of specific atoms is preferably 2 to 10 in one molecule. The upper limit of the numerical range is preferably 7 or less, more preferably 6 or less, and still more preferably 5 or less. Moreover, the lower limit of the numerical range is preferably 3 or more, and may be 4. In a case where the sensitizer has three or more specific atoms and thus a plurality of combinations of specific atoms can be recognized, the length of the atom chain is determined for all of the combinations of specific atoms, and the length of the atom chain may be 2 or 3 for at least one combination. The number of specific atom chains is preferably 2 or more in one molecule. The upper limit of the numerical range is preferably 6 or less, and may be 5 or 4. Moreover, the lower limit of the numerical range is preferably 3 or more. Furthermore, a specific atom chain may share a part of the atom chain with another specific atom chain. For example, in a case where the sensitizer is a compound having the following structure, the number of specific atoms is 5 (two nitrogen atoms and three sulfur atoms), the atom chains which can be said to be the specific atom chains are four atom chains including an atom chain between a first specific atom (S) and a second specific atom (S), an atom chain between a third specific atom (N) and a fourth specific atom (S), an atom chain between the fourth specific atom (S) and a fifth specific atom (N), and an atom chain between the fifth specific atom (N) and the third specific atom (N).

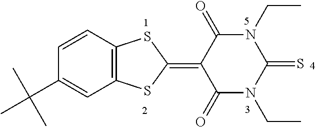 [SMILES: CCN1C(=O)C(=C2Sc3ccc(C(C)(C)C)cc3S2)C(=O)N(CC)C1=S]

In the present invention, the specific atom chain is preferably contained in a ring structure in the sensitizer. Consequently, the pattern collapse defects can be further suppressed. The ring structure may be a single ring or a polycyclic ring. The number of rings constituting the ring structure containing the specific atom chain is preferably 2 to 10. Moreover, the upper limit of the number of rings is more preferably 5 or less, and may be 4. Furthermore, the lower limit of the number of rings is more preferably 3 or more. The number of ring members (the number of atoms constituting the ring structure) in the ring structure containing the specific atom chain is preferably 4 to 30. Moreover, the upper limit of the number of ring members is more preferably 20 or less and still more preferably 16 or less, and may be 15. Furthermore, the lower limit of the number of ring members is more preferably 6 or more and still more preferably 9 or more, and may be 10.

In addition, the number of specific atoms contained in the ring structure is preferably 2 to 5, and may be 3 or 4. Preferred aspects of the ring structure containing the specific atom chain are, for example, the following ring structures. Moreover, the following ring structures are examples as partial structures contained in a chemical structure of the sensitizer, and the state of a bonding site is appropriately modified depending on other groups bonded to the following ring structures. A preferred aspect of the substituent is, for example, the aforementioned substituent T. In the present invention, the ring structure containing the specific atom chain is not limited to the following ring structures.

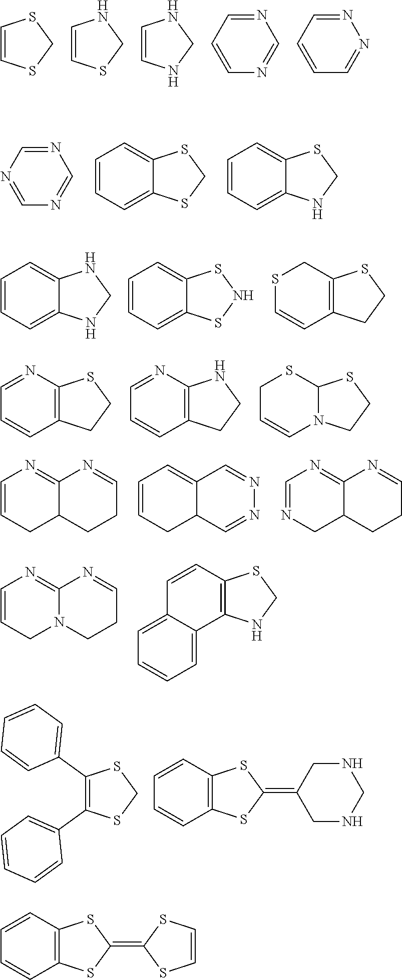

The composition for forming a pattern according to the embodiment of the present invention preferably contains a compound represented by Formula (PS-1) as the sensitizer. Consequently, the pattern collapse defects can be further suppressed.

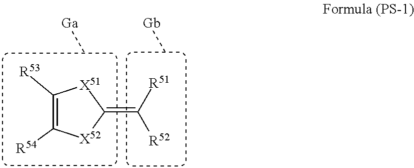

In Formula (PS-1),

X⁵¹ and X⁵² each independently represent —S— or —NR⁵⁵—, and R⁵⁵ represents a hydrogen atom or a monovalent substituent, and

R⁵¹ to R⁵⁴ each independently represent a hydrogen atom or a monovalent substituent, R⁵¹ and R⁵² may be bonded to each other to form a ring, and R⁵³ and R⁵⁴ may be bonded to each other to form a ring. Ga and Gb each indicate a partial structure in the compound.

It is preferable that at least one of X⁵¹ or X⁵² is —S— and more preferable that both are —S—. Moreover, regarding X⁵¹ and X⁵², one of them may be —S— and the other may be —NR⁵⁵—.

The monovalent substituent as R⁵⁵ is preferably the substituent T and more preferably a group represented by Formula (T-1).

-L^{a}-R^{a} Formula (T-1):

R^{a} in Formula (T-1) is preferably a hydrogen atom, a hydrocarbon group having 1 to 20 carbon atoms, or a heterocyclic group, more preferably a hydrogen atom or a hydrocarbon group having 1 to 10 carbon atoms, still more preferably a hydrogen atom or a hydrocarbon group having 1 to 6 carbon atoms, and particularly preferably a hydrogen atom or a hydrocarbon group having 1 to 3 carbon atoms. Moreover, the hydrocarbon group is preferably a linear, branched, or cyclic alkyl group, a linear, branched, or cyclic alkenyl group, or an aryl group.

In the linear, branched, or cyclic alkyl group as R^{a}, the structure is preferably linear or branched, and the number of carbon atoms is preferably 1 to 10, more preferably 1 to 6, and still more preferably 1 to 3. The alkyl group is, for example, preferably a methyl group, an ethyl group, an n-propyl group, an isopropyl group, an n-butyl group, or a t-butyl group, more preferably a methyl group or an ethyl group, and still more preferably a methyl group. Moreover, the alkyl group can have a substituent, and may be unsubstituted.

Further, in the linear, branched, or cyclic alkenyl group, the structure is preferably linear or branched, and the number of carbon atoms is preferably 2 to 10, more preferably 2 to 6, and still more preferably 2 or 3. The alkenyl group is, for example, preferably an ethenyl (vinyl) group, an n-propenyl group, an isopropenyl group, an n-butenyl group, or a t-butenyl group, more preferably an ethenyl group, an n-propenyl group, or an isopropenyl group, and still more preferably an isopropenyl group. Moreover, the alkenyl group can have a substituent, and may be unsubstituted.

Furthermore, the number of rings in the aryl group is preferably 1 to 5, more preferably 1 or 2, and still more preferably 1. The aryl group is, for example, preferably a phenyl group or a naphthyl group and more preferably a phenyl group. The aryl group can have a substituent, and may be unsubstituted.

In addition, the heterocyclic group may have aromaticity and non-aromaticity. The number of rings in the heterocyclic group is preferably 1 to 5, more preferably 1 or 2, and still more preferably 1. The heterocyclic group preferably contains at least one kind of an oxygen atom, a nitrogen atom, or a sulfur atom, more preferably contains at least one kind of an oxygen atom or a nitrogen atom, and still more preferably contains an oxygen atom. The heterocyclic group is, for example, a tetrahydrofuryl group, a tetrahydropyrrolyl group, a tetrahydrothienyl group, a furyl group, a pyrrolyl group, an imidazolyl group, a thienyl group, a benzofuryl group, an indolyl group, a benzothienyl group, and the like.

L^{a} in Formula (T-1) is a single bond or a divalent linking group. The divalent linking group is preferably one kind selected from an alkylene group having 1 to 5 carbon atoms, an alkenylene group having 2 to 5 carbon atoms, an arylene group, —CH═N—, —NH—, —O—, —C(═O)—, —S—, —S(═O)₂—, or —C(═S)—, or a group obtained by combining two or more kinds thereof.

The number of carbon atoms in the alkylene group as L^{a} is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring.

Specifically, the divalent linking group as L^{a} is preferably one kind selected from a methylene group, an ethylene group, a vinylene group, a phenylene group, —CH═N—, —NH—, —O—, —C(═O)—, —S—, —S(═O)₂—, or —C(═S)—, or a group obtained by combining two or more kinds thereof, and more preferably one kind selected from a methylene group, an ethylene group, —CH═N—, —NH—, —O—, or —C(═O)—, or a group obtained by combining two or more kinds thereof. Moreover, regarding the divalent linking group, a plurality of the same constituent elements may be selected within the same group. Furthermore, the divalent linking group can have a substituent, and may be unsubstituted.

A formula weight of the monovalent substituent represented by Formula (T-1) is preferably 15 to 300. The upper limit of the numerical range is more preferably 200 or less, still more preferably 160 or less, and particularly preferably 120 or less. Moreover, the lower limit of the numerical range is more preferably 20 or greater, still more preferably 30 or greater, and particularly preferably 35 or greater.

Preferred aspects of the monovalent substituent represented by Formula (T-1) are as follows, for example. However, in the present invention, the group represented by Formula (T-1) is not limited thereto.

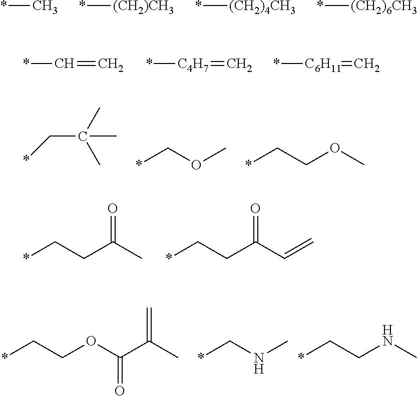

The monovalent substituent as R⁵¹ to R⁵⁴ in Formula (PS-1) is preferably the substituent T and more preferably a group represented by Formula (T-2).

-L^{b}-R^{b} Formula (T-2):

R^{b} in Formula (T-2) is preferably a hydrogen atom, a hydrocarbon group having 1 to 20 carbon atoms, or a heterocyclic group, more preferably a hydrogen atom or a hydrocarbon group having 1 to 10 carbon atoms, still more preferably a hydrogen atom or a hydrocarbon group having 1 to 6 carbon atoms, and particularly preferably a hydrogen atom or a hydrocarbon group having 1 to 3 carbon atoms. Moreover, similarly to a case of R^{a}, the hydrocarbon group is preferably a linear, branched, or cyclic alkyl group, a linear, branched, or cyclic alkenyl group, or an aryl group.

The linear, branched, or cyclic alkyl group as R^{b} is the same as in a case of R^{a}. The alkyl group is, for example, preferably a methyl group, an ethyl group, an n-propyl group, an isopropyl group, an n-butyl group, or a t-butyl group, preferably a methyl group or an ethyl group, and still more preferably a methyl group. Moreover, the alkyl group can have a substituent, and may be unsubstituted.

Moreover, the linear, branched, or cyclic alkenyl group is the same as in a case of R^{a}. The alkenyl group is, for example, preferably an ethenyl (vinyl) group, an n-propenyl group, an isopropenyl group, an n-butenyl group, or a t-butenyl group, preferably an ethenyl group, an n-propenyl group, or an isopropenyl group, and still more preferably an isopropenyl group. Moreover, the alkenyl group can have a substituent, and may be unsubstituted.

Further, the aryl group is the same as in a case of R^{a}. The aryl group is, for example, preferably a phenyl group or a naphthyl group and more preferably a phenyl group. The aryl group can have a substituent, and may be unsubstituted.

Furthermore, the heterocyclic group is the same as in a case of R^{a}. The heterocyclic group is, for example, a tetrahydrofuryl group, a tetrahydropyrrolyl group, a tetrahydrothienyl group, a furyl group, a pyrrolyl group, an imidazolyl group, a thienyl group, a benzofuryl group, an indolyl group, a benzothienyl group, and the like.

L^{b} in Formula (T-2) is a single bond or a divalent linking group. The divalent linking group is preferably one kind selected from an alkylene group having 1 to 5 carbon atoms, an alkenylene group having 2 to 5 carbon atoms, a conjugated oligoenediyl group, an arylene group, —CH═N—, —NH—, —O—, —C(═O)—, —S—, or —C(═S)—, or a group obtained by combining two or more kinds thereof.

The number of carbon atoms in the alkylene group as L^{b} is more preferably 1 to 3 and still more preferably 1 or 2. The number of carbon atoms in the alkenylene group is more preferably 2 or 3 and still more preferably 2. The conjugated oligoenediyl group means a divalent unsaturated hydrocarbon group having two to several dozen double bonds and having a structure in which double bonds and single bonds are alternately arranged, and the number of double bonds is preferably 2 to 5, more preferably 2 or 3, and still more preferably 2. The conjugated oligoenediyl group can also be said to be a group in which a plurality of vinylene groups (alkenylene groups having 2 carbon atoms) are combined. The arylene group may be a single ring or a polycyclic ring, and is preferably a single ring or a bicyclic ring and more preferably a single ring. One ring constituting the arylene group is preferably a 6-membered ring.

Specifically, the divalent linking group as L^{b} is more preferably one kind selected from a methylene group, an ethylene group, a vinylene group, a conjugated dienediyl group, a phenylene group, —CH═N—, —NH—, —O—, —C(═O)—, —S—, or —C(═S)—, or a group obtained by combining two or more kinds thereof, and still more preferably one kind selected from a methylene group, an ethylene group, a conjugated dienediyl group, a phenylene group, —CH═N—, —NH—, —O—, or —C(═O)—, or a group obtained by combining two or more kinds thereof. Moreover, regarding the divalent linking group, a plurality of the same constituent elements may be selected within the same group. Furthermore, L^{b} can have a substituent, and may be unsubstituted.

In addition, it is preferable that for at least one of R⁵¹, . . . , or R⁵⁴, L^{b} in Formula (T-2) is a π-conjugated linking group, more preferable that for at least three of R⁵¹, . . . , or R⁵⁴, L^{b} is a π-conjugated linking group, and still more preferable that for all of R⁵¹ to R⁵⁴, L^{b} is a π-conjugated linking group. The π-conjugated linking group is a linking group containing a bond having a delocalized π electron.

The π-conjugated linking group is preferably a linking group, which consists of one selected from the group consisting of —CR⁶⁰═CR⁶¹—, an arylene group, —CR⁶²═N—, —NR⁶³—, —O—, —C(═O)—, —S—, and —C(═S)—, or a combination of two or more thereof. Here, R⁶⁰ to R⁶³ each independently represent a hydrogen atom or a monovalent substituent, and R⁶⁰ and R⁶¹ may be bonded to each other to form a ring. It is more preferable that R⁶⁰ to R⁶³ are each independently a hydrogen atom, a methyl group, or an ethyl group. The arylene group is preferably a phenylene group. Moreover, regarding the π-conjugated linking group, a plurality of the same constituent elements may be selected within the same group.

That is, in the composition for forming a pattern according to the embodiment of the present invention, it is also preferable that the compound represented by Formula (PS-1) is a compound represented by Formula (PS-1a) or Formula (PS-1b). Consequently, the pattern collapse defects can be further suppressed. Symbols in Formula (PS-1a) and Formula (PS-1b) are as described above.

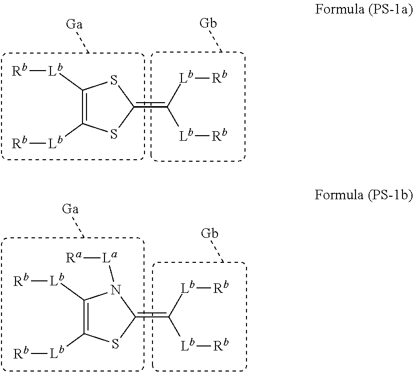

It is also preferable that the composition for forming a pattern according to the embodiment of the present invention contains a compound represented by Formula (PS-2) as the sensitizer. Consequently, the pattern collapse defects can be further suppressed.

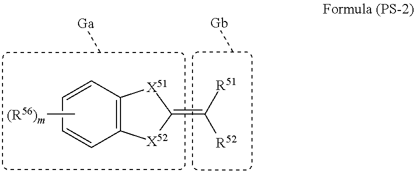

In Formula (PS-2),

X⁵¹ and X⁵² each independently represent —S— or —NR⁵⁵—, and R⁵⁵ represents a hydrogen atom or a monovalent substituent,

R⁵¹ and R⁵² each independently represent a hydrogen atom or a monovalent substituent, and R⁵¹ and R⁵² may be bonded to each other to form a ring,

R⁵⁶ represents a monovalent substituent, and

m represents an integer of 0 to 4.

X⁵¹ and X⁵² have the same definitions as X⁵¹ and X⁵² in Formula (PS-1), and it is preferable that at least one of them is —S— and more preferable that both are —S—. Moreover, regarding X⁵¹ and X⁵², one of them may be —S— and the other may be —NR⁵⁵—. R⁵⁵ as a monovalent substituent has the same definition as R⁵⁵ in Formula (PS-1).

R⁵¹ and R⁵² have the same definitions as R⁵¹ and R⁵² in Formula (PS-1), and the monovalent substituent as R⁵¹ or R⁵² is preferably the substituent T and more preferably a group represented by Formula (T-2).

R⁵⁶ is preferably the substituent T, and more preferably an alkyl group having 1 to 10 carbon atoms, an alkenyl group having 2 to 10 carbon atoms, an aryl group having 10 or less carbon atoms, or a heterocyclic group having 10 or less ring members.

The number of carbon atoms in the alkyl group as R⁵⁶ is preferably 1 to 5 and more preferably 2 to 4. In particular, the alkyl group is preferably a methyl group, an ethyl group, an n-propyl group, an isopropyl group, an n-butyl group, or a t-butyl group, more preferably an isopropyl group, an n-butyl group, or a t-butyl group, and still more preferably a t-butyl group. Moreover, the alkyl group can have a substituent, and may be unsubstituted.

The number of carbon atoms in the alkenyl group is preferably 2 to 5 and more preferably 2 to 4. In particular, the alkenyl group is, for example, preferably an ethenyl (vinyl) group, an n-propenyl group, an isopropenyl group, an n-butenyl group, or a t-butenyl group, more preferably an ethenyl group, an n-propenyl group, or an isopropenyl group, and still more preferably an isopropenyl group. Moreover, the alkenyl group can have a substituent, and may be unsubstituted.

The aryl group may be a single ring or a polycyclic ring, and is preferably a single ring or a bicyclic ring and more preferably a single ring. One ring constituting the aryl group is preferably a 6-membered ring. In particular, the aryl group is preferably a phenyl group or a naphthyl group. The heterocyclic group is the same as the heterocyclic group described for R^{a} in Formula (T-1).

m in Formula (PS-2) is preferably 1 to 3 and more preferably 1 or 2. In a case where m is 2 or greater, a plurality of R⁵⁶'s may be the same as or different from each other.

In the composition for forming a pattern according to the embodiment of the present invention, it is also preferable that the sensitizer represented by Formula (PS-2) is a compound represented by Formula (PS-3). Consequently, the pattern collapse defects can be further suppressed.

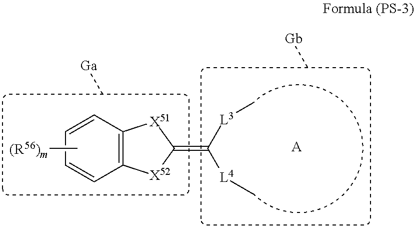

In Formula (PS-3),

X⁵¹, X⁵², R⁵⁶, and m have the same definitions as X⁵¹, X⁵², R⁵⁶, and m in Formula (PS-2), respectively,

L³ and L⁴ are each independently a divalent linking group, and at least one of L³ or L⁴ is a π-conjugated linking group, and

A represents a ring structure including L³ and L⁴.

Moreover, regarding the π-conjugated linking group, it is preferable that both L³ and L⁴ are π-conjugated linking groups, and more preferable that the entire ring structure A is a π-conjugated linking group which links two bonding sites of a carbon atom to which the ring structure A is bonded (that is, L³ and L⁴ are bonded to each other and thus the π-conjugated system goes around the ring structure A once).

The π-conjugated linking group is preferably a linking group, which consists of one selected from the group consisting of —CR⁶⁰═CR⁶¹—, an arylene group, —CR⁶²═N—, —NR⁶³—, —O—, —C(═O)—, —S—, and —C(═S)—, or a combination of two or more thereof. In the formulae, R⁶⁰ to R⁶³ each independently represent a hydrogen atom or a monovalent substituent, and R⁶⁰ and R⁶¹ may be bonded to each other to form a ring. It is more preferable that R⁶⁰ to R⁶³ are each independently a hydrogen atom, a methyl group, or an ethyl group. The arylene group is preferably a phenylene group. Furthermore, the π-conjugated linking group in the ring structure A preferably contains at least one of —NR⁶³— or —C(═O)—, and more preferably contains both —NR⁶³— and —C(═O)—. In particular, it is also preferable that the π-conjugated linking group in the ring structure A contains a plurality of —NR⁶³—'s and a plurality of —C(═O)—'s. Moreover, regarding the π-conjugated linking group, a plurality of the same constituent elements may be selected within the same group.

The ring structure A is preferably a 5- to 7-membered ring and more preferably a 5-membered ring or a 6-membered ring.

It is also preferable that the compound represented by Formula (PS-3) is a compound represented by Formula (PS-3a) or Formula (PS-3b). Consequently, the pattern collapse defects can be further suppressed.

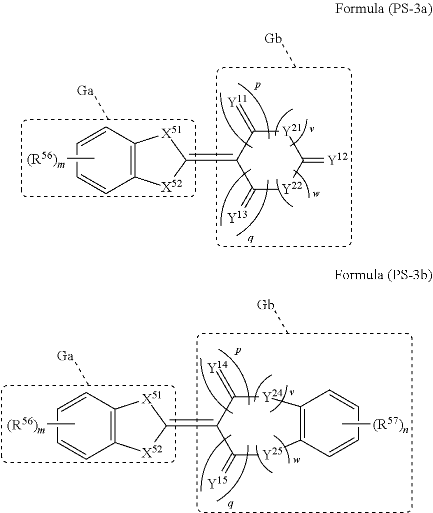

X⁵¹, X⁵², R⁵⁶, and m in Formula (PS-3a) and Formula (PS-3b) have the same definitions as X⁵¹, X⁵², R⁵⁶, and m in Formula (PS-2), respectively. Moreover, Y¹¹, Y¹², Y¹³, Y¹⁴, and Y¹⁵ are each independently an oxygen atom or a sulfur atom Y²¹, Y²², Y²⁴, and Y²⁵ are each independently —CR⁷⁰R⁷¹—, —O—, —NR⁷²—, or —S—, R⁷⁰ to R⁷² each represent a hydrogen atom or a monovalent substituent, R⁵⁷ represents a monovalent substituent, n represents an integer of 0 to 4, p and q are each 0 or 1, p+q satisfies 1 or 2, v and w are each 0 or 1, and v+w satisfies 1 or 2. Furthermore, p+q+v+w in Formula (PS-3a) is 3 or 4, and p+q+v+w in Formula (PS-3b) is 2 or 3.

In Formula (PS-3a), p+q may be 1 or 2, but is preferably 2. v+w may be 1 or 2, but is preferably 2.

In addition, it is preferable that at least one of Y¹¹, Y¹², or Y¹³ is an oxygen atom, more preferable that at least two thereof are oxygen atoms, and still more preferable that Y¹¹ and Y¹³ are oxygen atoms. In particular, regarding Y¹¹, Y¹², and Y¹³, an aspect in which all of Y¹¹, Y¹², and Y¹³ are oxygen atoms, or an aspect in which Y¹¹ and Y¹³ are oxygen atoms and Y¹² is a sulfur atom is preferable.

Y²¹ and Y²² are each preferably —O—, —NR⁷²—, or —S—, more preferably —O— or —NR⁷²—, and still more preferably —NR⁷²—. The monovalent substituent as R⁷⁰ to R⁷² is the same as the monovalent substituent as R⁵⁵, and more preferably the group represented by Formula (T-1), and the description in a case of R⁵⁵ is also similarly applied to the contents of R^{a} and L^{a} in Formula (T-1). Therefore, a preferred aspect of the monovalent substituent as R⁷⁰ is, for example, the substituent described as the preferred aspect of the monovalent substituent represented by Formula (T-1). In particular, it is preferable that R⁷⁰ to R⁷² are each independently a hydrogen atom, a methyl group, or an ethyl group.

In Formula (PS-3b), p+q may be 1 or 2, but is preferably 2. v+w may be 1 or 2, but is preferably 1.

Moreover, it is preferable that at least one of Y¹⁴ or Y¹⁵ is an oxygen atom and more preferable that both of them are oxygen atoms.

Similarly to cases of Y²¹ and Y²², Y²⁴ and Y²⁵ are each preferably —O—, —NR⁷²—, or —S—, more preferably —O— or —NR⁷²—, and still more preferably —NR⁷²—. R⁷⁰ to R⁷² are the same as in a case of Formula (PS-3a).

Similarly to R⁵⁶, R⁵⁷ in Formula (PS-3b) is preferably the substituent T, and more preferably an alkyl group having 1 to 10 carbon atoms, an alkenyl group having 2 to 10 carbon atoms, an aryl group having 10 or less carbon atoms, or a heterocyclic group having 10 or less ring members. The specific content of R⁵⁷ is also the same as that of R⁵⁶. n in Formula (PS-3b) is preferably 0 to 3 and more preferably 0 or 1, and may be 0. In a case where n is 2 or greater, a plurality of R⁵⁷'s may be the same as or different from each other.

Hereinafter, preferred aspects of the sensitizer according to the composition for forming a pattern according to the embodiment of the present invention will be shown. In the following description, first, the sensitizer is divided into a partial structure Ga and a partial structure Gb, which are shown in each of Formula (PS-1), Formula (PS-2), and Formula (PS-3), and preferred aspects of each partial structure are shown, and then preferred combinations of the partial structure Ga and the partial structure Gb will be described. However, in the present invention, the partial structure Ga, the partial structure Gb, and a combination thereof are not limited to the following aspects.

The preferred aspects of the partial structure Ga are as follows.

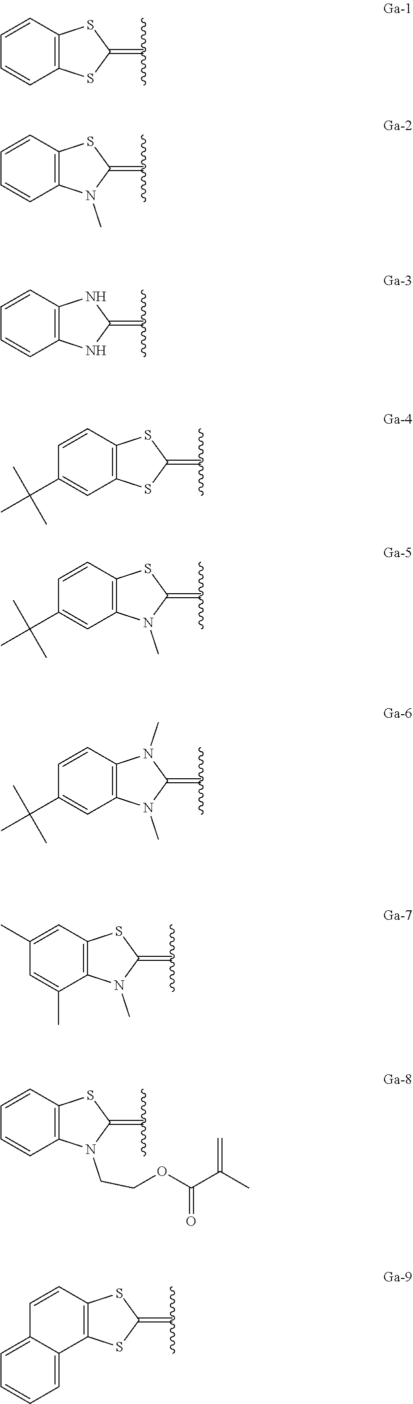

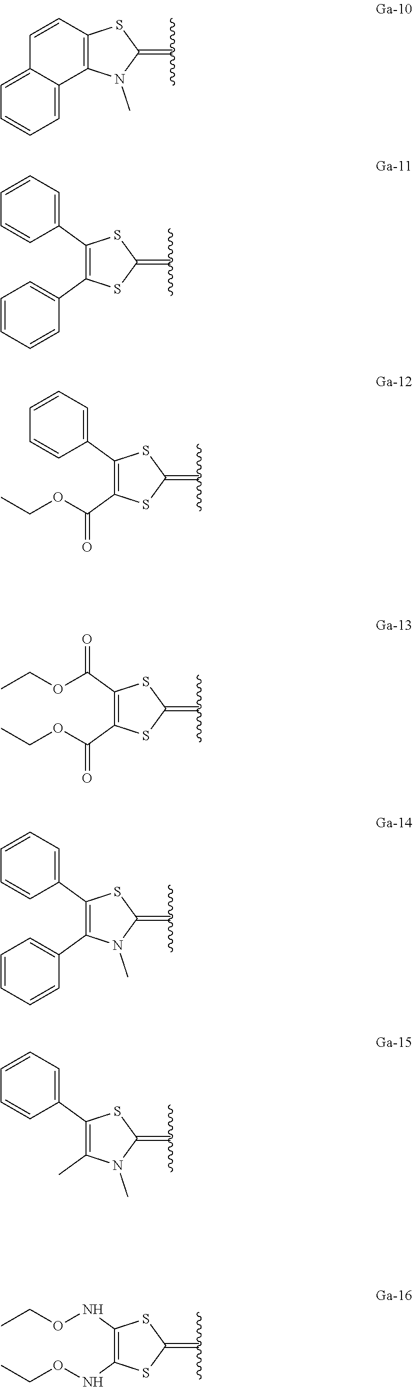

The preferred aspects of the partial structure Gb are as follows.

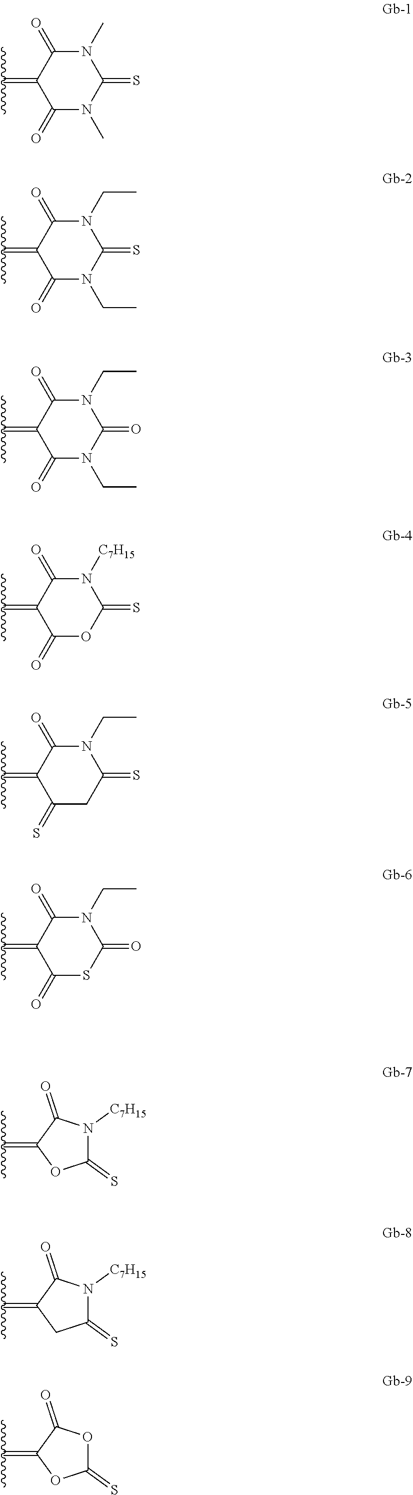

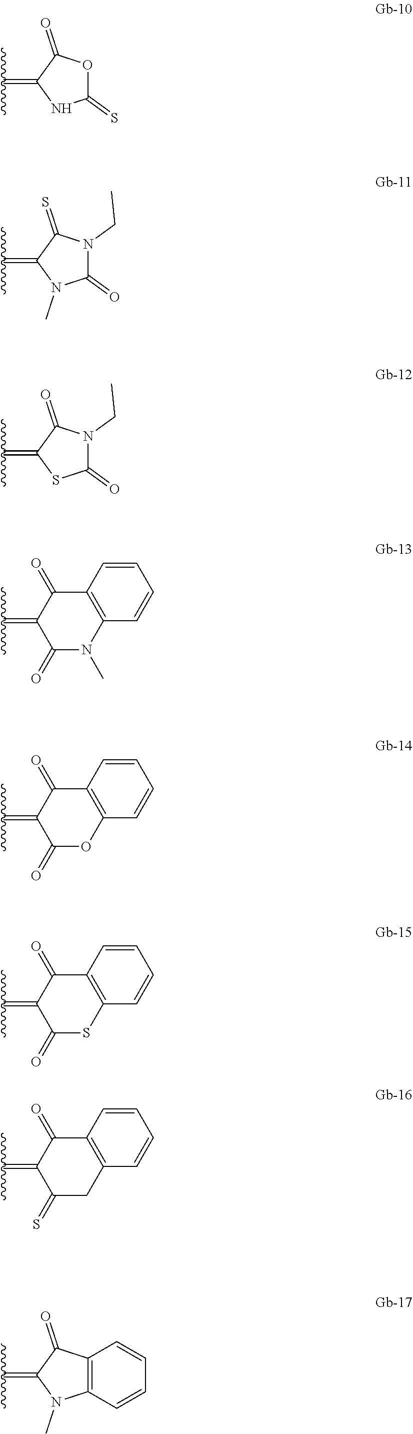

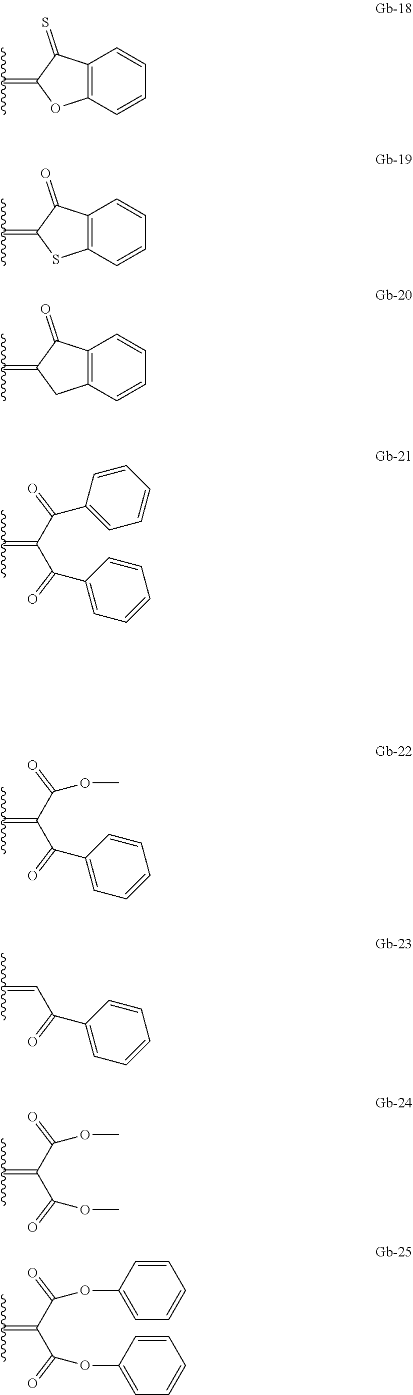

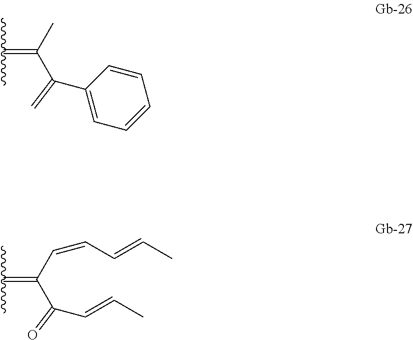 [SMILES: *=C(C)C(=C)c1ccccc1 ; *=C(/C=C\C=C\C)C(=O)/C=C/C]

The preferred combinations of the partial structure Ga and the partial structure Gb are as follows.

TABLE 1

| No. | Ga | Gb |
|---|---|---|
| 1 | Ga-1 | Gb-2 |
| 2 | Ga-1 | Gb-7 |
| 3 | Ga-1 | Gb-13 |
| 4 | Ga-2 | Gb-2 |
| 5 | Ga-2 | Gb-7 |
| 6 | Ga-2 | Gb-13 |
| 7 | Ga-4 | Gb-1 |
| 8 | Ga-4 | Gb-2 |
| 9 | Ga-4 | Gb-3 |
| 10 | Ga-4 | Gb-4 |
| 11 | Ga-4 | Gb-5 |
| 12 | Ga-4 | Gb-6 |
| 13 | Ga-4 | Gb-7 |
| 14 | Ga-4 | Gb-8 |
| 15 | Ga-4 | Gb-9 |
| 16 | Ga-4 | Gb-10 |
| 17 | Ga-4 | Gb-11 |
| 18 | Ga-4 | Gb-12 |
| 19 | Ga-4 | Gb-13 |
| 20 | Ga-4 | Gb-14 |
| 21 | Ga-4 | Gb-15 |
| 22 | Ga-4 | Gb-16 |
| 23 | Ga-4 | Gb-17 |
| 24 | Ga-4 | Gb-18 |
| 25 | Ga-4 | Gb-19 |
| 26 | Ga-4 | Gb-20 |
| 27 | Ga-4 | Gb-21 |
| 28 | Ga-4 | Gb-22 |
| 29 | Ga-4 | Gb-23 |
| 30 | Ga-4 | Gb-24 |
| 31 | Ga-4 | Gb-25 |
| 32 | Ga-4 | Gb-26 |
| 33 | Ga-4 | Gb-27 |
| 34 | Ga-5 | Gb-2 |
| 35 | Ga-5 | Gb-7 |
| 36 | Ga-5 | Gb-13 |
| 37 | Ga-7 | Gb-2 |
| 38 | Ga-7 | Gb-7 |
| 39 | Ga-7 | Gb-13 |
| 40 | Ga-8 | Gb-1 |
| 41 | Ga-8 | Gb-2 |
| 42 | Ga-8 | Gb-3 |
| 43 | Ga-8 | Gb-4 |
| 44 | Ga-8 | Gb-5 |
| 45 | Ga-8 | Gb-6 |
| 46 | Ga-8 | Gb-7 |
| 47 | Ga-8 | Gb-8 |
| 48 | Ga-8 | Gb-9 |

TABLE 2

| No. | Ga | Gb |
|---|---|---|
| 49 | Ga-8 | Gb-10 |
| 50 | Ga-8 | Gb-11 |
| 51 | Ga-8 | Gb-12 |
| 52 | Ga-8 | Gb-13 |
| 53 | Ga-8 | Gb-14 |
| 54 | Ga-8 | Gb-15 |
| 55 | Ga-8 | Gb-16 |
| 56 | Ga-8 | Gb-17 |
| 57 | Ga-8 | Gb-18 |
| 58 | Ga-8 | Gb-19 |
| 59 | Ga-8 | Gb-20 |
| 60 | Ga-8 | Gb-21 |
| 61 | Ga-8 | Gb-22 |
| 62 | Ga-8 | Gb-23 |
| 63 | Ga-8 | Gb-24 |
| 64 | Ga-8 | Gb-25 |
| 65 | Ga-8 | Gb-26 |
| 66 | Ga-8 | Gb-27 |
| 67 | Ga-9 | Gb-2 |
| 68 | Ga-9 | Gb-7 |
| 69 | Ga-9 | Gb-13 |
| 70 | Ga-10 | Gb-2 |
| 71 | Ga-10 | Gb-3 |
| 72 | Ga-10 | Gb-7 |
| 73 | Ga-10 | Gb-13 |
| 74 | Ga-10 | Gb-14 |
| 75 | Ga-10 | Gb-20 |
| 76 | Ga-10 | Gb-21 |
| 77 | Ga-10 | Gb-23 |
| 78 | Ga-10 | Gb-26 |
| 79 | Ga-11 | Gb-2 |
| 80 | Ga-11 | Gb-3 |
| 81 | Ga-11 | Gb-7 |
| 82 | Ga-11 | Gb-13 |
| 83 | Ga-11 | Gb-14 |
| 84 | Ga-11 | Gb-20 |
| 85 | Ga-11 | Gb-21 |
| 86 | Ga-11 | Gb-23 |
| 87 | Ga-11 | Gb-26 |
| 88 | Ga-13 | Gb-2 |
| 89 | Ga-13 | Gb-3 |
| 90 | Ga-13 | Gb-7 |
| 91 | Ga-13 | Gb-13 |
| 92 | Ga-13 | Gb-14 |
| 93 | Ga-13 | Gb-20 |
| 94 | Ga-13 | Gb-21 |
| 95 | Ga-13 | Gb-23 |
| 96 | Ga-13 | Gb-26 |

The sensitizer preferably exhibits a light absorption coefficient of 25.0 L/(g·cm) or greater in a wavelength range of 400 nm or greater. That is, regarding the absorption spectrum characteristics of the sensitizer, it is preferable that a wavelength range λ₂₅ exhibiting a light absorption coefficient of 25.0 L/(g·cm) or greater is present and at least a part of the wavelength range λ₂₅ is in a wavelength range of 400 nm or greater. Consequently, the sensitizer can efficiently absorb light of 400 nm or greater, and the pattern collapse defects can be further suppressed. The upper limit wavelength of the wavelength range λ₂₅ is preferably 445 nm or less and more preferably 440 nm or less. Moreover, the lower limit wavelength of the wavelength range λ₂₅ is preferably 380 nm or greater, more preferably 390 nm or greater, and still more preferably 400 nm or greater.

In the composition for forming a pattern according to the embodiment of the present invention, the content of the sensitizer is preferably 0.0001% to 3% by mass with respect to the amount of the total solid content. The content is more preferably 1.5% by mass or less, still more preferably 1.0% by mass or less, and particularly preferably 0.8% by mass or less. Moreover, the content is more preferably 0.001% by mass or greater, still more preferably 0.01% by mass or greater, and particularly preferably 0.05% by mass or greater. Furthermore, Cs/Ci, which is a mass ratio of a content Cs of the sensitizer to a content Ci of the photopolymerization initiator, is preferably 0.0002 to 1.5. The mass ratio Cs/Ci is more preferably 1.0 or less, still more preferably 0.5 or less, and particularly preferably 0.3 or less. Moreover, the mass ratio is more preferably 0.0005 or greater, still more preferably 0.002 or greater, even more preferably 0.01 or greater, and particularly preferably 0.02 or greater. The sensitizer is used alone or in combination of a plurality thereof, and in a case where two or more kinds of the sensitizers are used, the total amount thereof is preferably included within the above range.

<<Release Agent>>

The composition for forming a pattern according to the embodiment of the present invention may contain a release agent.

A kind of the release agent used in the present invention is not particularly specified as long as the kind does not depart from the spirit of the present invention. The release agent is preferably an additive having a function of segregating at an interface with the mold to promote separation from the mold. The composition for forming a pattern according to the embodiment of the present invention preferably contains, as the release agent, at least one kind of (a) a surfactant, (b) a non-polymerizable compound (hereinafter, also referred to as a “non-polymerizable compound having releasability”) which has a polyalkylene glycol structure having at least one hydroxyl group at a terminal or having an etherified hydroxyl group, or (c) a polymerizable compound having a fluorine atom.

The release agent in the composition for forming a pattern may be of only one kind or two or more kinds. Moreover, in a case where the release agents are contained, a total content thereof with respect to the total solid content is preferably 0.1% to 20% by mass, more preferably 0.5% to 10% by mass, and still more preferably 1% to 5% by mass. In a case where two or more kinds of the release agents are used, the total amount thereof is preferably included within the above range.

<<<(a) Surfactant>>>

As a surfactant for the release agent, any one of a nonionic surfactant, an anionic surfactant, a cationic surfactant, or an amphoteric surfactant may be used. Moreover, the surfactant preferably includes at least one kind of a nonionic surfactant or an anionic surfactant and more preferably includes a nonionic surfactant, from the viewpoint of compatibility with other components or releasability.

The nonionic surfactant is a compound having at least one hydrophobic moiety and at least one nonionic hydrophilic moiety. The hydrophobic moiety and the nonionic hydrophilic moiety may each be at a terminal of a molecule, or inside. The hydrophobic moiety is constituted of a hydrophobic group selected from a hydrocarbon group, a fluorine-containing group, and a Si-containing group, and the number of carbon atoms in the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxyl group, a phenolic hydroxyl group, an ether group (preferably, a polyoxyalkylene group and a cyclic ether group), an amide group, an imide group, a ureide group, a urethane group, a cyano group, a sulfonamide group, a lactone group, a lactam group, and a cyclocarbonate group. The nonionic surfactant may be a hydrocarbon-based, fluorine-based, Si-based, or fluorine and Si-based nonionic surfactant, but is more preferably a fluorine-based or Si-based nonionic surfactant and still more preferably a fluorine-based nonionic surfactant. Here, the “fluorine and Si-based surfactant” refers to a surfactant satisfying requirements of both a fluorine-based surfactant and a Si-based surfactant.

Examples of a commercially available product of the fluorine-based nonionic surfactant include FLUORAD FC-4430 and FC-4431 produced by Sumitomo 3M Limited, SURFLON S-241, S-242, S-243, and S-650 produced by AGC SEIMI CHEMICAL CO., LTD., EFTOP EF-PN31M-03, EF-PN31M-04, EF-PN31M-05, EF-PN31M-06, and MF-100 produced by Mitsubishi Materials Electronic Chemicals Co., Ltd., Polyfox PF-636, PF-6320, PF-656, and PF-6520 produced by OMNOVA Solutions Inc., FUTAGENT 250, 251, 222F, 212M, and DFX-18 produced by NEOS COMPANY LIMITED, UNIDYNE DS-401, DS-403, DS-406, DS-451, and DSN-403N produced by DAIKIN INDUSTRIES, LTD., MEGAFACE F-430, F-444, F-477, F-553, F-556, F-557, F-559, F-562, F-565, F-567, F-569, and R-40 produced by DIC Corporation, and Capstone FS-3100 and Zonyl FSO-100 produced by DuPont.

In addition, examples of the anionic surfactant include alkyl ether phosphate, polyoxyalkylene alkyl ether phosphate, alkyl alcohol phosphoric acid ester salt, alkylbenzene sulfonate, alkyl alcohol sulfuric acid ester salt, and polyoxyalkylene alkyl ether sulfate. Examples of the cationic surfactant include tetraalkylammonium halide, alkylpyridinium halide, and alkylimidazoline halide. Examples of the amphoteric surfactant include alkyl betaine and lecithin.

In a case where the composition for forming a pattern according to the embodiment of the present invention contains a surfactant, a content of the surfactant is preferably 0.1% to 10% by mass, more preferably 0.2% to 5% by mass, and still more preferably 0.5% to 5% by mass, with respect to the amount of the total solid content in the composition. The composition for forming a pattern may contain only one kind or two or more kinds of the surfactants. In a case where two or more kinds thereof are contained, the total amount thereof is preferably within the above range.

<<<(b) Non-Polymerizable Compound having Releasability>>>

In the composition for forming a pattern according to the embodiment of the present invention, the non-polymerizable compound having releasability is not particularly limited as long as the non-polymerizable compound has a polyalkylene glycol structure having at least one hydroxyl group at the terminal or having an etherified hydroxyl group, and it is preferable that a fluorine atom and a silicon atom are not substantially contained. Here, the non-polymerizable compound refers to a compound having no polymerizable group. Moreover, regarding the non-polymerizable compound, the expression “a fluorine atom and a silicon atom are not substantially contained” indicates, for example, that a total content ratio of the fluorine atom and the silicon atom is 1% by mass or less, and it is preferable that a fluorine atom and a silicon atom are not contained at all. In a case where a fluorine atom and a silicon atom are not contained, compatibility with the polymerizable compound is improved, and particularly in the composition for forming a pattern which does not substantially contain a solvent, coating uniformity, pattern formability during imprinting, and line edge roughness after dry etching are improved.

The polyalkylene glycol structure of the non-polymerizable compound having releasability is preferably a polyalkylene glycol structure including an alkylene group having 1 to 6 carbon atoms, more preferably a polyethylene glycol structure, a polypropylene glycol structure, a polybutylene glycol structure, or a mixed structure thereof, still more preferably a polyethylene glycol structure, a polypropylene glycol structure, or a mixed structure thereof, and even more preferably a polypropylene glycol structure.

Furthermore, the non-polymerizable compound may be substantially constituted of only a polyalkylene glycol structure, except for a substituent at a terminal. Here, the expression “substantially” means that constituent elements other than the polyalkylene glycol structure account for 5% by mass or less and preferably 1% by mass or less of the entire compound. In particular, it is preferable to include a compound substantially consisting of a polypropylene glycol structure, as the non-polymerizable compound having releasability.

The number of alkylene glycol constitutional units included in the polyalkylene glycol structure is preferably 3 to 100, more preferably 4 to 50, still more preferably 5 to 30, and even more preferably 6 to 20.

The non-polymerizable compound having releasability preferably has at least one hydroxyl group at the terminal or has an etherified hydroxyl group. In a case where the non-polymerizable compound has at least one hydroxyl group at the terminal or has an etherified hydroxyl group, the remaining terminal may be a hydroxyl group, or a hydrogen atom of the terminal hydroxyl group may be substituted. As a group in which a hydrogen atom of the terminal hydroxyl group may be substituted, an alkyl group (that is, polyalkylene glycol alkyl ether) and an acyl group (that is, polyalkylene glycol ester) are preferable. A compound having a plurality of (preferably, two or three) polyalkylene glycol chains via a linking group can also be preferably used.

Preferred specific examples of the non-polymerizable compound having releasability include polyethylene glycol, polypropylene glycol (for example, produced by FUJIFILM Wako Pure Chemical Corporation), mono or dimethyl ether thereof, mono or dibutyl ether, mono or dioctyl ether, mono or dicetyl ether, monostearic acid ester, monooleic acid ester, polyoxyethylene glyceryl ether, polyoxypropylene glyceryl ether, polyoxyethylene lauryl ether, and trimethyl ether thereof.

A weight-average molecular weight of the non-polymerizable compound having releasability is preferably 150 to 6,000, more preferably 200 to 3,000, still more preferably 250 to 2,000, and even more preferably 300 to 1,200.

In addition, examples of a commercially available product of the non-polymerizable compound having releasability, which can be used in the present invention, include OLFINE E1010 (produced by Nissin Chemical Co., Ltd.) and Brij35 (produced by Kishida Chemical Co., Ltd.).

In a case where the composition for forming a pattern according to the embodiment of the present invention contains the non-polymerizable compound having releasability, a content of the non-polymerizable compound having releasability is preferably 0.1% by mass or greater, more preferably 0.5% by mass or greater, still more preferably 1.0% by mass or greater, and even more preferably 2% by mass or greater, in the total solid content. Moreover, the content is preferably 20% by mass or less, more preferably 10% by mass or less, and still more preferably 5% by mass or less.

The composition for forming a pattern may contain only one kind or two or more kinds of the non-polymerizable compounds having releasability. In a case where two or more kinds thereof are contained, the total amount thereof is preferably within the above range.

<<<(c) Polymerizable Compound having Fluorine Atom>>>

The polymerizable compound having a fluorine atom as the release agent in the present invention preferably has a polymerizable group, and a functional group containing a fluorine atom.

The kind of the polymerizable group is not particularly limited, but, for example, an ethylenically unsaturated bond-containing group, an epoxy group, and the like are preferable, and an ethylenically unsaturated bond-containing group is more preferable. As described above, as the ethylenically unsaturated bond-containing group, for example, a vinyl group, an ethynyl group, a (meth)acryloyl group, a (meth)acryloyloxy group, and the like are preferable, a (meth)acryloyl group and a (meth)acryloyloxy group are more preferable, and an acryloyl group and an acryloyloxy group are still more preferable.

As the functional group containing a fluorine atom, a fluorine-containing group selected from a fluoroalkyl group and a fluoroalkyl ether group is preferable.

The fluoroalkyl group is preferably a fluoroalkyl group having 2 or more carbon atoms and more preferably a fluoroalkyl group having 4 or more carbon atoms, and the upper limit value of the number of carbon atoms is not particularly specified, but is preferably 20 or less, more preferably 8 or less, and still more preferably 6 or less. The fluoroalkyl group is most preferably a fluoroalkyl group having 4 to 6 carbon atoms. Specifically, the fluoroalkyl group is preferably a trifluoromethyl group, a pentafluoroethyl group, a heptafluoropropyl group, a hexafluoroisopropyl group, a nonafluorobutyl group, a tridecafluorohexyl group, or a heptadecafluorooctyl group. Moreover, it is also preferable that the fluoroalkyl group has a trifluoromethyl group at a terminal or a side chain.

The fluoroalkyl ether group is preferably a perfluoroethyleneoxy group or a perfluoropropyleneoxy group, for example. Moreover, similarly to a case of the fluoroalkyl group, it is also preferable that the fluoroalkyl ether group has a trifluoromethyl group at the terminal, or has a trifluoromethyl group at the side chain as in —(CF(CF₃)CF₂O)—.

The polymerizable compound having a fluorine atom is also described in paragraphs 0021 to 0043 of JP2011-124554A, the contents of which are incorporated in the present specification.

In a case where the composition for forming a pattern according to the embodiment of the present invention contains the polymerizable compound having a fluorine atom, a content of the polymerizable compound having a fluorine atom is preferably 0.1% by mass or greater, more preferably 0.5% by mass or greater, still more preferably 1.0% by mass or greater, and even more preferably 2% by mass or greater, in the total solid content. Moreover, the content is preferably 20% by mass or less, more preferably 10% by mass or less, and still more preferably 5% by mass or less. The composition for forming a pattern may contain only one kind or two or more kinds of the polymerizable compounds having a fluorine atom. In a case where two or more kinds thereof are contained, the total amount thereof is preferably within the above range.

<<Other Components>>

The composition for forming a pattern according to the embodiment of the present invention may contain a sensitizer, an antioxidant, an ultraviolet absorber, a solvent, a polymer, or the like, in addition to the aforementioned components. Each of these compounds in the composition for forming a pattern may be of only one kind or two or more kinds. For the details thereof, reference can be made to the description in paragraphs 0061 to 0064 of JP2014-170949A, the contents of which are incorporated in the present specification.

<<<Solvent>>>

The composition for forming a pattern according to the embodiment of the present invention may contain a solvent. Examples of the solvent include propylene glycol monomethyl ether acetate, cyclohexanone, 2-heptanone, γ-butyrolactone, propylene glycol monomethyl ether, and ethyl lactate. In a case where the solvent is contained, a content thereof is preferably 1% to 20% by mass with respect to the composition. Only one kind or two or more kinds of the solvents may be contained. In a case where two or more kinds thereof are contained, the total amount thereof is preferably within the above range.

Furthermore, in the present invention, a configuration in which a solvent is not substantially contained can also be adopted. The expression “solvent is not substantially contained” means that the content of the solvent is 5% by mass or less, and the content is preferably 3% by mass or less and more preferably 1% by mass or less.

<<<Polymer>>>

The composition for forming a pattern according to the embodiment of the present invention may contain a polymer. The polymer is, for example, a component having a weight-average molecular weight of 2,000 or greater, and preferably a component having a weight-average molecular weight of greater than 2,000.

Furthermore, in the present invention, a configuration in which a polymer is not substantially contained can also be adopted. The expression “polymer is not substantially contained” means that the content of the polymer is 5% by mass or less, and the content is preferably 3% by mass or less and more preferably 1% by mass or less.

<Characteristics of Composition for Forming Pattern>

In the composition for forming a pattern according to the embodiment of the present invention, a viscosity at 23° C. is preferably 50 mPa·s or lower. Moreover, the viscosity is preferably 12 mPa·s or lower, more preferably 11 mPa·s or lower, still more preferably 10 mPa·s or lower, even more preferably 9 mPa·s or lower, and further still more preferably 8 mPa·s or lower. The lower limit value of the viscosity is not particularly specified, but can be, for example, 5 mPa·s or higher. By setting the viscosity within the above range, the composition for forming a pattern according to the embodiment of the present invention is more likely to enter into the mold, and thus mold filling time can be shortened. Moreover, the pattern formability and the throughput can also be further improved. In the composition for forming a pattern according to the embodiment of the present invention, surface tension at 23° C. is preferably 25 to 40 mN/m. Moreover, the surface tension is preferably 38 mN/m or lower, more preferably 36 mN/m or lower, and still more preferably 35 mN/m or lower. Furthermore, the surface tension is preferably 27 mN/m or higher and more preferably 28 mN/m or higher.

An Ohnishi parameter of the composition for forming a pattern according to the embodiment of the present invention is preferably 4.0 or less, more preferably 3.9 or less, still more preferably 3.8 or less, even more preferably 3.6 or less, and particularly preferably 3.5 or less. The lower limit value of the Ohnishi parameter is not particularly specified, but can be, for example, 2.8 or greater. By setting the Ohnishi parameter to 4.0 or less, etching processing characteristics, in particular, pattern disconnection after etching can be further effectively suppressed.

In the composition for forming a pattern according to the embodiment of the present invention, a maximum light absorption coefficient of the composition for forming a pattern in a wavelength range of 400 nm to 500 nm is preferably 1.0 L/(g·cm) or less. Moreover, the maximum light absorption coefficient is preferably 0.8 L/(g·cm) or less and more preferably 0.6 L/(g·cm) or less, and by doing so, light reaches a deep portion of the composition for forming a pattern and thus the pattern collapse defects can be further suppressed.

<Method for Producing Composition for Forming Pattern>

The composition for forming a pattern according to the embodiment of the present invention is prepared by formulating raw materials (the respective materials described above) in a predetermined ratio. It is preferable that the raw materials are mixed and then the mixture is subjected to a filtration treatment with a filter. The filtration with a filter is preferably performed after the raw materials for the composition for forming a pattern are mixed.

Effects of filtration are exhibited even with one stage of a filter, but filtration with two or more stages of filters is more preferable. The filtration with two or more stages of filters refers to filtration in a state where two or more filters are arranged in series. In the present invention, filtration with one to four stages of filters is preferable, and filtration with two to four stages of filters is more preferable.

A component (material component) constituting the material for the filter preferably includes a resin. The resin is not particularly limited, and resins well known as the material for the filter can be used. As one preferred embodiment of the component (material component) constituting the material for the filter, a polymer (grafted polymer) in which at least one kind of neutral groups is grafted can be mentioned. The neutral group is preferably at least one kind selected from a hydroxyl group or a carboxy group, and more preferably a hydroxyl group. The grafted polymer is preferably a grafted polyolefin and more preferably a grafted polyethylene. For the description of the grafted polymer, reference can be made to the description in WO2016/081729A, the contents of which are incorporated in the present specification.

A pore diameter of the filter used in the present invention is preferably 100 nm or smaller, more preferably 20 nm or smaller, still more preferably 12 nm or smaller, and even more preferably 8 nm or smaller, and may be 5 nm or smaller. By setting the pore diameter of the filter to 100 nm or smaller, impurities can be further effectively reduced. Moreover, the lower limit value of the pore diameter of the filter is not particularly specified, but is preferably 1 nm or larger, for example. By setting the pore diameter of the filter to 1 nm or larger, an unnecessarily large pressure is not applied during filtration, productivity is improved, and breakage of a filter can be effectively suppressed. In a case where the filtration is performed stepwise, a filter having a pore diameter of 100 to 7 nm (preferably, a filter having a pore diameter of 20 to 7 nm) can be used in first-stage filtration, and a filter having a pore diameter of smaller than 7 nm (preferably, a filter having a pore diameter of smaller than 7 nm and 1 nm or larger) can be used in second-stage filtration. Moreover, a difference in the pore diameter from the immediately preceding stage, such as between the first stage and the second stage and between the second stage and the third stage, is preferably 1 to 8 nm.

<Storage Container>

As a storage container of the composition for forming a pattern according to the embodiment of the present invention, a storage container well known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

<Pattern Producing Method>

The composition for forming a pattern according to the embodiment of the present invention is applied in a layer form onto the substrate to form a layered film, and then cured by exposure, which will be described later, to form a cured substance. Here, the laminate including the substrate and the layered film that has not been cured corresponds to a laminate according to the embodiment of the present invention, and the cured substance corresponds to a cured film according to the embodiment of the present invention. The layered film may be a continuous film such as a film formed by, for example, a spin coating method, or may be a discontinuous film such as a film formed by, for example, an ink jet method. The composition for forming a pattern according to the embodiment of the present invention is used for producing a patterned cured substance (hereinafter, also simply referred to as a “pattern”) by an optical imprinting method.

A pattern producing method according to the embodiment of the present invention includes applying the composition for forming a pattern according to the embodiment of the present invention onto a substrate or a mold and irradiating the composition for forming a pattern with light in a state where the composition for forming a pattern is sandwiched between the mold and the substrate. The method for applying the composition for forming a pattern onto the substrate or the mold is not particularly limited. Regarding the application method, reference can be made to the description in paragraph 0102 of JP2010-109092A (the corresponding US application is the specification of US2011/0199592A), the contents of which are incorporated in the present specification. In the present invention, as the application method, a spin coating method or an ink jet method is preferable.

In the present invention, the substrate is not particularly limited. Regarding the substrate, reference can be made to the description in paragraph 0103 of JP2010-109092A (the corresponding US application is the specification of US2011/0199592A), the contents of which are incorporated in the present specification. Specific examples thereof include a silicon substrate, a glass substrate, a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Furthermore, specific examples of a material for the glass substrate include aluminosilicate glass, aluminoborosilicate glass, and barium borosilicate glass. In the present invention, as the substrate, a silicon substrate is preferable.

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. In the present invention, as the mold, a quartz mold is preferable. A pattern (line width) of the mold used in the present invention preferably has a size of 50 nm or less.

The composition for forming a pattern is irradiated with light in a state of being sandwiched between the mold and the substrate. A step of performing pressure contact with the substrate or the mold can be preferably performed under a rare gas atmosphere, under a reduced-pressure atmosphere, or under a pressure-reduced rare gas atmosphere. Here, the reduced-pressure atmosphere means a state in a space filled with a pressure lower than the atmospheric pressure (101,325 Pa), and the pressure is preferably 1,000 Pa or lower, more preferably 100 Pa or lower, and still more preferably 1 Pa or lower. In a case where the rare gas is used, helium is preferable. An exposure amount is desirably in a range of 5 mJ/cm² to 1,000 mJ/cm².

The light used for curing the composition for forming a pattern according to the embodiment of the present invention is not particularly limited, and examples thereof include a high-energy ionizing radiation, light having a wavelength in a near-ultraviolet, far-ultraviolet, visible, or infrared range, and a radiation. As the high-energy ionizing radiation source, for example, electron beams accelerated by an accelerator such as a Cockcroft-type accelerator, a Van de Graaff accelerator, a linear accelerator, a betatron, or a cyclotron are the most conveniently and economically in the industrial aspect, but in addition to the electron beams, radiations such as γ-rays, X-rays, α-rays, neutron rays, and proton beams which are radiated from a radioactive isotope, a nuclear reactor, or the like can also be used. Examples of the ultraviolet ray source include an ultraviolet fluorescent lamp, a low-pressure mercury lamp, a high-pressure mercury lamp, an ultra-high pressure mercury lamp, a xenon lamp, a carbon arc lamp, and a sun lamp. The radiation includes, for example, microwaves and EUV. Moreover, an LED, semiconductor laser light, or laser light, which is used in fine processing of a semiconductor, such as 248-nm KrF excimer laser light or a 193-nm ArF excimer laser can also be suitably used in the present invention. As the light, monochromatic light may be used, or light (mixed light) having a plurality of different wavelengths may be used.

The light which can be used for the exposure is, for example, light having a wavelength of 200 to 450 nm. Specifically, examples of the irradiation light during the exposure include ultraviolet rays such as a g-line (wavelength of 436 nm) and an i-line (wavelength of 365 nm). The exposure using the i-line may be performed while cutting light having a wavelength shorter than 300 nm, as described in KR10-2017-0122130A.

During the exposure, exposure illuminance is preferably in a range of 1 mW/cm² to 10,000 mW/cm². By setting the exposure illuminance to 1 mW/cm² or greater, an exposure time can be shortened, and thus productivity is improved, and by setting the exposure illuminance to 10,000 mW/cm² or less, there is a tendency that the deterioration in characteristics of a permanent film due to the occurrence of side reactions can be restrained. An exposure amount is preferably in a range of 5 mJ/cm² to 10,000 mJ/cm². In a case where the exposure amount is less than 5 mJ/cm², an exposure margin gets narrow, photocuring is insufficient, and thus a problem such as attachment of an unreacted substance to the mold is more likely to occur. Meanwhile, in a case where the exposure amount is greater than 10,000 mJ/cm², a risk of deterioration of the permanent film due to decomposition of the composition arises.

Furthermore, during the exposure, in order to prevent the inhibition of radical polymerization by oxygen, an oxygen concentration may be controlled to be lower than 100 mg/L by flowing an inert gas such as nitrogen or argon.

In the pattern producing method according to the embodiment of the present invention, after a pattern forming layer (layered composition for forming a pattern) is cured by the light irradiation, as necessary, a step of applying heat to the cured pattern to further cure the pattern may be included. A temperature for heating and curing the composition according to the embodiment of the present invention after the light irradiation is, for example, preferably 150° C. to 280° C. and more preferably 200° C. to 250° C. Moreover, a time for applying heat is preferably 5 to 60 minutes and more preferably 15 to 45 minutes.

In addition, during the exposure, light may be continuously radiated for the exposure, or may be radiated in the form of a pulse for the exposure (pulse exposure). Moreover, the pulse exposure is an exposure method in which exposure is performed by repeating irradiation with light and resting in a cycle of a short time (for example, a millisecond level or less). In a case of the pulse exposure, a pulse width is preferably 100 nanoseconds (ns) or less, more preferably 50 nanoseconds or less, and still more preferably 30 nanoseconds or less. The lower limit of the pulse width is not particularly limited, but may be 1 femtosecond (fs) or greater and may be 10 femtoseconds or greater. A frequency is preferably 1 kHz or greater, more preferably 2 kHz or greater, and still more preferably 4 kHz or greater. The upper limit of the frequency is preferably 50 kHz or less, more preferably 20 kHz or less, and still more preferably 10 kHz or less. Maximum instantaneous illuminance is preferably 5,000 W/cm² or greater, more preferably 10,000 W/cm² or greater, and still more preferably 20,000 W/cm² or greater. Moreover, the upper limit of the maximum instantaneous illuminance is preferably 100,000 W/cm² or less, more preferably 80,000 W/cm² or less, and still more preferably 50,000 W/cm² or less. Furthermore, the pulse width is a time during which light is radiated in the pulse period. The frequency is the number of pulse periods per second. The maximum instantaneous illuminance is average illuminance within the time during which light is radiated in the pulse period. The pulse period is a period in which irradiation with light and resting are one cycle in the pulse exposure.

In the composition for forming a pattern according to the embodiment of the present invention, an underlayer film or a liquid film may be provided between the substrate and a layer formed of the composition for forming a pattern, by using a composition for forming an underlayer film or a composition for forming a liquid film. That is, the composition for forming a pattern (further, a pattern of the present invention) may be provided directly on the surface of the substrate or the mold, or may be provided on the substrate or the mold via one or more layers. The underlayer film and the liquid film will be described in detail later.

In addition to the aforementioned matters, for details of the pattern producing method, reference can be made to the description in paragraphs 0103 to 0115 of JP2010-109092A (the corresponding US application is the specification of US2011/0199592A), the contents of which are incorporated in the present specification.

In the pattern producing method according to the embodiment of the present invention, a fine pattern can be formed at a low cost and with high accuracy by the optical imprinting method (more preferably, an optical nanoimprinting method). Therefore, the pattern, which was used to be formed by using the photolithography technique in the related art, can be formed with higher accuracy and at a lower cost. As an example, the method is used for manufacturing a semiconductor element. That is, the present invention also discloses a method for manufacturing a semiconductor element, which includes the pattern producing method according to the embodiment of the present invention. More specifically, the pattern of the present invention is preferably used as an etching resist (etching mask). In particular, the pattern can also be applied as a permanent film, such as an overcoat layer or an insulating film, used in a liquid crystal display (LCD) or the like, or an etching resist such as a semiconductor integrated circuit, a recording material, or a flat panel display. In particular, the pattern obtained by the pattern producing method according to the embodiment of the present invention also has excellent etching resistance, and thus can also be preferably used as an etching resist for dry etching using fluorocarbon or the like.

<Pattern>

As described above, the pattern formed by the pattern producing method according to the embodiment of the present invention can be used as a permanent film used in an LCD or the like, or an etching resist for semiconductor processing. Moreover, a grid pattern is formed on a glass substrate of the LCD using the pattern of the present invention, and thus a polarizing plate having low reflection or absorption and a large screen size (for example, 55 inches, or greater than 60 inches) can be manufactured at a low cost. For example, the polarizing plate described in JP2015-132825A or W02011/132649A can be manufactured. Furthermore, 1 inch is 25.4 mm.

In addition, after the production, the composition for forming a pattern is bottled in a container such as a gallon bottle or a coated bottle, transported, and stored, but in this case, for the purpose of preventing deterioration, the inside of the container may be replaced with inert nitrogen, argon, or the like. Moreover, during the transportation and the storage, the temperature may be a normal temperature, but in order to further prevent degeneration of the composition for forming a pattern, the temperature may be controlled to be in a range of −20° C. to 0° C. It goes without saying that blocking light at a level at which the reaction does not proceed is preferable.

Specifically, the pattern of the present invention can be preferably used for producing a recording medium such as a magnetic disc, a light-receiving element such as a solid-state imaging element, a light emitting element such as an LED and organic EL, an optical device such as an LCD, an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

The pattern formed by the pattern producing method according to the embodiment of the present invention is also useful as an etching resist (mask for lithography). In a case where the pattern is used as an etching resist, first, a silicon substrate (silicon wafer or the like) in which a thin film of, for example, SiO₂ or the like is formed or the like is used as a substrate, and a fine pattern of, for example, a nano or micro order is formed on the substrate by the pattern producing method according to the embodiment of the present invention. In the present invention, the pattern producing method is particularly advantageous in that a fine pattern of a nano order can be formed and a pattern having a size of 100 nm or less, further 50 nm or less, and particularly 30 nm or less can also be formed. The lower limit value of the size of the pattern formed by the pattern producing method according to the embodiment of the present invention is not particularly specified, but can be, for example, 1 nm or greater. A shape of the pattern is not particularly specified, but, for example, an aspect including at least one shape of a line, a hole, or a pillar is exemplified.

Thereafter, by performing etching with an etching gas such as hydrogen fluoride or the like in a case of wet etching and CF₄ or the like in a case of dry etching, a desired pattern can be formed on the substrate. The pattern has favorable etching resistance particularly to dry etching. That is, the pattern obtained by the producing method according to the embodiment of the present invention is preferably used as an etching mask. Moreover, the present invention also discloses a method for manufacturing a semiconductor element, in which etching is performed using, as a mask, the pattern obtained by the producing method according to the embodiment of the present invention.

<Composition for Forming Underlayer Film>

As described above, by providing the underlayer film between the substrate and the layer formed of the composition for forming a pattern, effects such as improvement in the adhesiveness between the substrate and the layer formed of the composition for forming a pattern can be achieved. In the present invention, the underlayer film can be obtained by applying the composition for forming an underlayer film onto the substrate and then curing the composition, in the same manner as the composition for forming a pattern. Hereinafter, each component of the composition for forming an underlayer film will be described.

The composition for forming an underlayer film of the present invention contains a curable component. The curable component is a component constituting the underlayer film, and may be any one of a high-molecular-weight component (for example, a molecular weight is greater than 1,000) or a low-molecular-weight component (for example, a molecular weight is less than 1,000). Specific examples thereof include a resin and a crosslinking agent. Each of these components may be used alone or in combination of two or more kinds thereof.

A total content of the curable components in the composition for forming an underlayer film is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or less.

A concentration of the curable component in the composition for forming an underlayer film (including a solvent) is not particularly limited, but is preferably 0.01% by mass or higher, more preferably 0.05% by mass or higher, and still more preferably 0.1% by mass or higher. The upper limit thereof is preferably 10% by mass or lower, more preferably 5% by mass or lower, still more preferably 1% by mass or lower, and even more preferably lower than 1% by mass.

<<Resin>>

As the resin in the composition for forming an underlayer film, well-known resins can be widely used. The resin used in the present invention preferably has at least one of a radically polymerizable group or a polar group, and more preferably has both a radically polymerizable group and a polar group.

By having the radically polymerizable group, an underlayer film having excellent hardness can be obtained. Moreover, by having a polar group, adhesiveness to a substrate is improved. Furthermore, in a case where a crosslinking agent is formulated, a crosslinking structure formed after curing is further firmed, and thus hardness of the obtained underlayer film can be improved.

The radically polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, a (meth)acryloyl group and a vinyl group are preferable, a (meth)acryloyl group is more preferable, and a (meth)acryloyloxy group is still more preferable. The ethylenically unsaturated bond-containing group defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxy group, or a hydroxyl group, more preferably at least one kind of an alcoholic hydroxyl group, a phenolic hydroxyl group, or a carboxy group, and still more preferably an alcoholic hydroxyl group or a carboxy group. The polar group defined here is referred to as a polar group Po. The polar group is preferably a nonionic group.

The resin in the composition for forming an underlayer film may further contain a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at least one kind of a (meth)acrylic resin, a vinyl resin, or a novolac resin is preferable.

A weight-average molecular weight of the resin is preferably 4,000 or greater, more preferably 6,000 or greater, and still more preferably 8,000 or greater. The upper limit thereof is preferably 1,000,000 or less and may be 500,000 or less.

The resin preferably has at least one of constitutional units represented by Formulae (1) to (3).

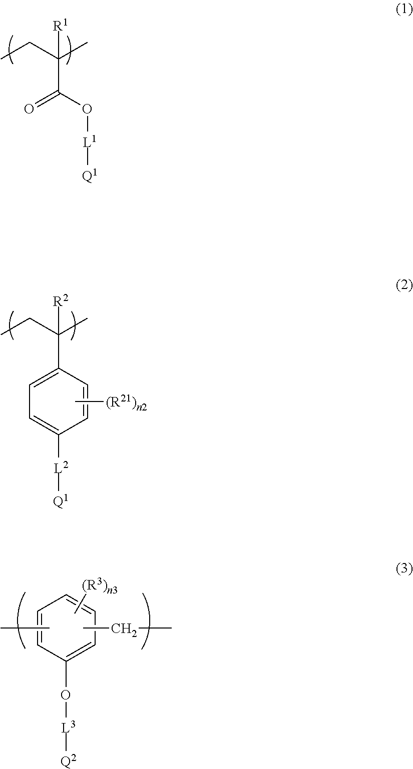

In the formulae, R¹ and R² are each independently a hydrogen atom or a methyl group. R²¹ and R³ are each independently a substituent. L¹, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are each preferably a methyl group.

R²¹ and R³ are each independently preferably the substituent T.

In a case where there are a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring Cf) (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocyclic ring (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocyclic ring (rings exemplified below are referred to as a ring Co) (a furan ring, a pyran ring, an oxirane ring, an oxetane ring, a tetrahydrofuran ring, a tetrahydropyran ring, a dioxane ring, and the like), and a sulfur-containing heterocyclic ring (rings exemplified below are referred to as a ring Cs) (a thiophene ring, a thiirane ring, a thietane ring, a tetrahydrothiophene ring, a tetrahydrothiopyran ring, and the like).

In a case where there are a plurality of R³'s, R³'s may be linked to each other to form a cyclic structure. Examples of the formed cyclic structure include ring Cf, the ring Cr, the ring Cn, the ring Co, and the ring Cs.

It is preferable that L¹, L², and L³ are each independently a single bond or a linking group L which will be described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxyl group as a substituent is also preferable. In the present specification, the “(oligo)alkyleneoxy group” means a divalent linking group having one or more “alkyleneoxy” constitutional units. The number of carbon atoms in an alkylene chain in the constitutional unit may be the same or different for every constitutional unit.

n2 is preferably 0 or 1 and more preferably 0. n3 is preferably 0 or 1 and more preferably 0.

Q¹ is preferably the ethylenically unsaturated bond-containing group Et.

Q² is preferably a polar group, and preferably an alkyl group having an alcoholic hydroxyl group.

The resin may further contain at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

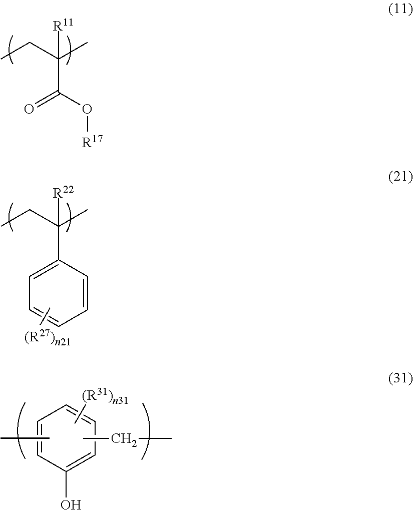

In the formulae, R¹¹ and R²² are each independently a hydrogen atom or a methyl group. R¹⁷ is a substituent. R²⁷ is a substituent. n21 is an integer of 0 to 5. R³¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po, and more preferably the polar group Po or the substituent T substituted with the polar group Po. In a case where R¹⁷ is a group containing a cyclic ether group, R¹⁷ is preferably a group containing the cyclic ether group Cyt, and more preferably the substituent T substituted with the cyclic ether group Cyt.

R²⁷ is a substituent, and at least one of R²⁷'s is preferably a polar group. The substituent is preferably the substituent T. n21 is preferably 0 or 1 and more preferably 0. In a case where there are a plurality of R²⁷'s, R²⁷'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there are a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of carbon atoms is preferably 1 to 24, more preferably 1 to 12, and still more preferably 1 to 6), an alkenylene group (the number of carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the repetition number is preferably 1 to 50, more preferably 1 to 40, and still more preferably 1 to 30), an arylene group (the number of carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxyl group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂—(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and as necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

The resin may be used alone or in combination of a plurality thereof.

As the resin as the curable component, in addition to the aforementioned resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

<<Crosslinking Agent>>

The crosslinking agent in the composition for forming an underlayer film is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and thus a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

<<Other Components>>

The composition for forming an underlayer film of the present invention may contain other components in addition to the aforementioned components.

Specifically, one or more kinds of a solvent, a thermal acid generator, an alkylene glycol compound, a polymerization initiator, a polymerization inhibitor, an antioxidant, a leveling agent, a thickener, a surfactant, or the like may be contained. Regarding the aforementioned components, the respective components described in JP2013-036027A, JP2014-090133A, and JP2013-189537A can be used. Also regarding the content or the like, reference can be made to the description in the aforementioned publications.

<<<Solvent>>>

In the present invention, the composition for forming an underlayer film particularly preferably contains a solvent (hereinafter, also referred to as a “solvent for an underlayer film”). The solvent is, for example, preferably a compound which is liquid at 23° C. and has a boiling point of 250° C. or lower. A content of the solvent for an underlayer film in the composition for forming an underlayer film is preferably 99.0% by mass or greater and more preferably 99.2% by mass or greater, and may be 99.4% by mass or greater. That is, the concentration of the total solid content in the composition for forming an underlayer film is preferably 1% by mass or lower, more preferably 0.8% by mass or lower, and still more preferably 0.6% by mass or lower. Moreover, the lower limit value thereof is preferably higher than 0% by mass, more preferably 0.001% by mass or higher, still more preferably 0.01% by mass or higher, and even more preferably 0.1% by mass or higher. By setting the proportion of the solvent within the above range, a film thickness during film formation is kept thin, and thus pattern formability during etching processing tends to be improved.

Only one kind or two or more kinds of the solvents may be contained in the composition for forming an underlayer film. In a case where two or more kinds thereof are contained, the total amount thereof is preferably within the above range.

A boiling point of the solvent for an underlayer film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the underlayer film, which is preferable.

The solvent for an underlayer film is preferably an organic solvent. The solvent is preferably a solvent having any one or more of an ester group, a carbonyl group, a hydroxyl group, or an ether group. Among them, it is preferable to use an aprotic polar solvent.

Examples of a preferred solvent among the solvents for an underlayer film include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether and lactone are particularly preferable.

<<<Thermal Acid Generator>>>

The thermal acid generator is a compound which generates an acid by heating and advances crosslinking by the action of the acid. In a case of being used in combination with the crosslinking agent, an underlayer film having higher hardness can be obtained.

As the thermal acid generator, an organic onium salt compound in which a cationic component and an anionic component are paired is usually used. As the cationic component, for example, organic sulfonium, organic oxonium, organic ammonium, organic phosphonium, and organic iodonium can be mentioned. Moreover, as the anionic component, for example, BF⁴⁻, B(C₆F₅)⁴⁻, SbF⁶⁻, AsF⁶⁻, PF⁶⁻, CF₃SO₃⁻, C₄F₉SO₃⁻, and (CF₃SO₂)₃C⁻ can be mentioned.

Specifically, reference can be made to the description in paragraphs 0243 to 0256 of JP2017-224660A and paragraph 0016 of JP2017-155091A, the contents of which are incorporated in the present specification.

A content of the thermal acid generator is preferably 0.01 to 10 parts by mass and more preferably 0.1 to 5 parts by mass, with respect to 100 parts by mass of the crosslinking agent. The thermal acid generator may be used alone or in combination of two or more kinds thereof. In a case where two or more kinds thereof are used, the total amount thereof is preferably within the above range.

<<<Polymerization Initiator>>>

The composition for forming an underlayer film may contain a polymerization initiator and preferably contains at least one kind of a thermal polymerization initiator or a photopolymerization initiator. By containing the polymerization initiator, a reaction of a polymerizable group contained in the composition for forming an underlayer film is promoted, and thus the adhesiveness tends to be improved. From the viewpoint that crosslinking reactivity with the composition for forming a pattern is improved, a photopolymerization initiator is preferable. As the photopolymerization initiator, a radical polymerization initiator and a cationic polymerization initiator are preferable, and a radical polymerization initiator is more preferable. Moreover, in the present invention, a plurality of kinds of photopolymerization initiators may be used in combination.

As a radical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of JP2016-027357A, the contents of which are incorporated in the present specification.

Examples of the acylphosphine compound include 2,4,6-trimethylbenzoyl-diphenyl-phosphine oxide.

In addition, as the photopolymerization initiator, commercially available initiators can also be used. Examples of such an initiator are the same as the commercially available initiators exemplified as the initiators which can be used, for example, in the composition for forming a pattern.

In a case where the photopolymerization initiator used in the composition for forming an underlayer film is formulated, a content thereof in the total solid content is, for example, 0.0001% to 5% by mass, preferably 0.0005% to 3% by mass, and more preferably 0.01% to 1% by mass. In a case where two or more kinds of photopolymerization initiators are used, the total amount thereof is within the above range.

<Composition for Forming Liquid Film>

In addition, in the present invention, it is also preferable that a liquid film is formed on the underlayer film by using a composition for forming a liquid film containing a radically polymerizable compound which is a liquid at 23° C. and 1 atm. In the present invention, the liquid film can be obtained by applying the composition for forming a liquid film onto the substrate and then drying the composition, in the same manner as the composition for forming a pattern. By forming such a liquid film, there are effects that the adhesiveness between the substrate and the composition for forming a pattern is further improved, and that the wettability of the composition for forming a pattern on the substrate is also improved. Hereinafter, the composition for forming a liquid film will be described.

The viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or higher. The viscosity is measured according to the following method.

The viscosity is measured using an E-type rotational viscometer RE85L manufactured by TOKI SANGYO CO., LTD. and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

<<Radically Polymerizable Compound A>>

The composition for forming a liquid film contains a radically polymerizable compound (radically polymerizable compound A) which is a liquid at 23° C. and 1 atm.

A viscosity of the radically polymerizable compound A at 23° C. is preferably 1 to 100,000 mPa·s. The lower limit thereof is preferably 5 mPa·s or higher and more preferably 11 mPa·s or higher. The upper limit thereof is preferably 1,000 mPa·s or lower and more preferably 600 mPa·s or lower.

The radically polymerizable compound A may be a monofunctional radically polymerizable compound having only one radically polymerizable group in one molecule, or a polyfunctional radically polymerizable compound having two or more radically polymerizable groups in one molecule. The monofunctional radically polymerizable compound and the polyfunctional radically polymerizable compound may be used in combination. Among them, for a reason of suppressing pattern collapse, the radically polymerizable compound A contained in the composition for forming a liquid film preferably includes a polyfunctional radically polymerizable compound, more preferably includes a radically polymerizable compound having two to five radically polymerizable groups in one molecule, still more preferably includes a radically polymerizable compound having two to four radically polymerizable groups in one molecule, and particularly preferably includes a radically polymerizable compound having two radically polymerizable groups in one molecule.

Furthermore, the radically polymerizable compound A preferably contains at least one of an aromatic ring (the number of carbon atoms is preferably 6 to 22, more preferably 6 to 18, and still more preferably 6 to 10) or an alicyclic ring (the number of carbon atoms is preferably 3 to 24, more preferably 3 to 18, and still more preferably 3 to 6), and more preferably contains an aromatic ring. The aromatic ring is preferably a benzene ring. Moreover, a molecular weight of the radically polymerizable compound A is preferably 100 to 900.

Examples of the radically polymerizable group of the radically polymerizable compound A include ethylenically unsaturated bond-containing groups, such as a vinyl group, an allyl group, and a (meth)acryloyl group, and a (meth)acryloyl group is preferable.

It is also preferable that the radically polymerizable compound A is a compound represented by Formula (I-1).

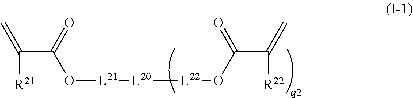

L²⁰ is a (1+q2)-valent linking group, and examples thereof include (1+q2)-valent linking groups which contains a group (the number of carbon atoms is preferably 1 to 12, more preferably 1 to 6, and still more preferably 1 to 3) having an alkane structure, a group (the number of carbon atoms is preferably 2 to 12, more preferably 2 to 6, and still more preferably 2 or 3) having an alkene structure, a group (the number of carbon atoms is preferably 6 to 22, more preferably 6 to 18, and still more preferably 6 to 10) having an aryl structure, a group (the number of carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, and a 7-membered ring are preferable) having a heteroaryl structure, or a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group containing at least one kind selected from a group having an aryl structure or a group having a heteroaryl structure, and more preferably a linking group containing a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other via or without via the linking group L to form a ring. L²⁰, L²¹, and L²² may have the substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the radically polymerizable compound A, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the radically polymerizable compound A in the composition for forming a liquid film is preferably 0.01% by mass or greater, more preferably 0.05% by mass or greater, and still more preferably 0.1% by mass or greater. The upper limit thereof is preferably 10% by mass or less, more preferably 5% by mass or less, and still more preferably 1% by mass or less.

The content of the radically polymerizable compound A in the solid content of the composition for forming a liquid film is preferably 50% by mass or greater, more preferably 75% by mass or greater, and still more preferably 90% by mass or greater. The upper limit thereof may be 100% by mass. The radically polymerizable compound A may be used alone or in combination of two or more kinds thereof. In a case where two or more kinds thereof are used, the total amount thereof is preferably within the above range.

Furthermore, it is also preferable that the solid content of the composition for forming a liquid film substantially consists of the radically polymerizable compound A. The case where the solid content of the composition for forming a liquid film substantially consists of the radically polymerizable compound A means that the content of the radically polymerizable compound A in the solid content of the composition for forming a liquid film is 99.9% by mass or greater, the content is more preferably 99.99% by mass or greater, and it is still more preferable that the solid content consists of the radically polymerizable compound A.

<<Solvent>>

The composition for forming a liquid film preferably contains a solvent (hereinafter, referred to as a “solvent for a liquid film” in some cases). Examples of the solvent for a liquid film include the solvents described in the aforementioned section of the solvent for an underlayer film, and these solvents can be used. A content of the solvent for a liquid film in the composition for forming a liquid film is preferably 90% by mass or greater and more preferably 99% by mass or greater, and may be 99.99% by mass or greater.

A boiling point of the solvent for a liquid film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the liquid film, which is preferable.

<<Radical Polymerization Initiator>>

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, and an oxime compound are preferable.

In addition, as the radical polymerization initiator, commercially available initiators can also be used. Examples of such an initiator are the same as the commercially available initiators exemplified as the initiators which can be used, for example, in the composition for forming a pattern.

In a case where the radical polymerization initiator is contained, the content thereof with respect to the solid content of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above range.

<<Other Components>>

The composition for forming a liquid film may contain one or more kinds of a polymerization inhibitor, an antioxidant, a leveling agent, a thickener, a surfactant, or the like, in addition to the aforementioned components.

<Kit>

A kit according to the embodiment of the present invention includes a combination of the composition for forming a pattern, which is for forming a pattern (cured film) for imprinting, and a composition for forming an underlayer film, which is for forming an underlayer film for imprinting. By using the kit according to the embodiment of the present invention, imprinting having excellent releasability can be performed. The composition for forming an underlayer film particularly preferably contains the resin having a radically polymerizable group, and an organic solvent. Furthermore, the kit according to the embodiment of the present invention preferably includes a composition for forming a liquid film containing a polymerizable compound which is a liquid at 23° C. and 1 atm.

### EXAMPLES

Hereinafter, the present invention will be described in more detail with reference to Examples. The materials, the used amounts, the ratios, the treatment details, the treatment procedures, and the like shown in the following Examples can be appropriately modified without departing from the spirit of the present invention. Therefore, the scope of the present invention is not limited to the specific examples described below. Unless otherwise specified, “parts” and “%” are based on mass.

<Preparation of Composition for Forming Pattern>

For Examples and Comparative Examples in Tables 4 to 8 below, a composition was prepared by mixing the polymerizable compound, photopolymerization initiator, release agent, and sensitizer shown in the tables in each of formulation ratios shown in the tables, and further adding 4-hydroxy-2,2,6,6-tetramethylpiperidine-1-oxyl free radical (produced by Tokyo Chemical Industry Co., Ltd.) as a polymerization inhibitor so that the amount thereof was 100 to 300 ppm by mass (0.01% to 0.03% by mass) with respect to the polymerizable compound. Moreover, each of the compositions was filtered in multiple stages with a polytetrafluoroethylene (PTFE)-made filter having a pore diameter of 0.1 μm, a nylon-made filter having a pore diameter of 0.02 μm, and a PTFE-made filter having a pore diameter of 0.003 μm, to prepare a composition for forming a pattern. Furthermore, the units of the formulation ratios of the polymerizable compound, photopolymerization initiator, release agent, and sensitizer in the tables are each parts by mass.

<Measurement>

The measurement of the following characteristics was performed for each raw material, and each composition for forming a pattern of Examples and Comparative Examples, as necessary.

<<Viscosity>>

For Examples and Comparative Examples in Tables 4 to 8, the viscosity (unit: mPa·s) of the composition for forming a pattern, which had not been cured, was measured under a temperature condition of 23° C.±0.2° C. using a RE-80L-type rotational viscometer manufactured by TOKI SANGYO CO., LTD. A rotation speed during the measurement was adjusted as shown in Table 3 below according to the viscosity.

TABLE 3

| Viscosity | Appropriate rotation speed |
|---|---|
| [mPa · s] | [rpm] |
| 0.001 or higher and lower than 6.077 | 100 |
| 6.077 or higher and lower than 12.16 | 50 |
| 12.16 or higher and lower than 30.39 | 20 |
| 30.39 or higher and lower than 60.77 | 10 |
| 60.77 or higher and lower than 121.6 | 5 |
| 121.6 or higher and lower than 303.9 | 2 |
| 303.9 or higher and lower than 607.7 | 1 |
| 607.7 or higher and lower than 1216 | 0.5 |
| 1216 or higher and lower than 2025 | 0.3 |

<<Surface Tension>>

For each composition for forming a pattern of Examples and Comparative Examples in Tables 4 to 8, the surface tension (unit: mN/m) was measured using a surface tensiometer SURFACE TENS-IOMETER CBVP-A3 manufactured by Kyowa Interface Science Co., LTD. This measurement was performed under a temperature condition of 23° C. after adding the composition dropwise onto a glass plate. Two samples were produced for one kind of composition for forming a pattern and respectively measured three times. Moreover, an arithmetic mean value of actually measured values of a total of six times was adopted as surface tension.

TABLE 4

| | | Example 1 | Example 2 | Example 3 | Example 4 | Example 5 | Example 6 | Example 7 | Example 8 |
|---|---|---|---|---|---|---|---|---|---|
| Polymerizable | A-1 | 60 | 60 | 50 | | | | 60 | 60 |
| compound | A-2 | | | 23 | 47 | | | | |
| | A-3 | 20 | 20 | | | | 30 | 20 | 20 |
| | A-4 | | | | | 50 | | | |
| | A-5 | | | | | | 48 | | |
| | A-6 | | | | 37 | 35 | | | |
| | A-7 | | | | 9 | 8 | | | |
| | A-8 | 13 | 13 | 20 | | | 15 | 13 | 13 |
| | A-9 | | | | | | | | |
| | A-10 | | | | | | | | |
| | A-11 | | | | | | | | |
| Photopolymerization | B-1 | 2 | 2 | | | 3.9 | | 2 | 1.9 |
| initiator | B-2 | | | 2 | | | 2 | | |
| | B-3 | | | | 2 | | | | |
| | B-4 | | | | | | | | |
| | B-5 | | | | | | | | |
| | B-6 | 1.9 | 1.9 | | | | 1.2 | 1.9991 | |
| | B-7 | | | 1.7 | 1.5 | | | | |
| | B-8 | | | | | | | | |
| Release agent | C-1 | 3 | 3 | | | | | | |
| | C-2 | | | 3 | | | | 3 | 3 |
| | C-3 | | | | 3 | | | | |
| | C-4 | | | | | 3 | | | |
| | C-5 | | | | | | 3 | | |
| Sensitizer | D-1 | 0.1 | | | | | | 0.0009 | 2.1 |
| | D-2 | | | | | | | | |
| | D-3 | | | | | | | | |
| | D-4 | | | | | | | | |
| | D-5 | | | | | | | | |
| | D-6 | | 0.1 | | | | | | |
| | D-7 | | | 0.3 | | | | | |
| | D-8 | | | | 0.5 | | | | |
| | D-9 | | | | | 0.1 | | | |
| | D-10 | | | | | | 0.8 | | |
| | D-11 | | | | | | | | |
| | D-12 | | | | | | | | |
| | D-13 | | | | | | | | |
| | D-14 | | | | | | | | |
| | D-15 | | | | | | | | |

| | | | | | | | | |
|---|---|---|---|---|---|---|---|---|
| Viscosity: mPa · s | 7.2 | 7.2 | 6.1 | 5.9 | 10 | 15 | 7 | 6.9 |
| Surface tension: mN/m | 34.1 | 33.9 | 33.2 | 30.9 | 29.8 | 33.2 | 33.9 | 34 |
| Evaluation of collapse defects | A | A | A | A | A | A | A | B |
| (condition A) | | | | | | | | |
| Evaluation of collapse defects | A | B | B | B | B | B | B | B |
| (condition B) | | | | | | | | |
| Evaluation of reaction speed | A | B | B | B | B | B | B | B |
| Evaluation of filling properties | A | A | A | B | B | B | A | A |
| Evaluation of releasability | A | A | B | B | A | A | A | B |

TABLE 5

| | | | Example | Example | Example | Example | Example | Example | Example |
|---|---|---|---|---|---|---|---|---|---|
| | | Example 9 | 10 | 11 | 12 | 13 | 14 | 15 | 16 |
| Polymerizable | A-1 | 59.9 | 60.8 | 60 | 60 | 60 | 60 | 60 | 70 |
| compound | A-2 | | | | | | | | |
| | A-3 | 20 | 20 | 20 | 20 | 20 | 20 | 20 | 20 |
| | A-4 | | | | | | | | |
| | A-5 | | | | | | | | |
| | A-6 | | | | | | | | |
| | A-7 | | | | | | | | |
| | A-8 | 13 | 13 | 13 | 13 | 13 | 13 | 13 | 3 |
| | A-9 | | | | | | | | |
| | A-10 | | | | | | | | |
| | A-11 | | | | | | | | |
| Photopolymerization | B-1 | 3 | | | | | | | 2 |
| initiator | B-2 | | 2 | | | | | | |
| | B-3 | | | | | | | | |
| | B-4 | | | | | | | | |
| | B-5 | | | | | | | | |
| | B-6 | 1.098 | | 3.9 | 1.9 | 1.9 | | | 1.9 |
| | B-7 | | | | 2 | | 3.9 | | |
| | B-8 | | | | | 2 | | 3.9 | |
| Release agent | C-1 | 3 | | 3 | 3 | 3 | 3 | 3 | 3 |
| | C-2 | | 3 | | | | | | |
| | C-3 | | | | | | | | |
| | C-4 | | | | | | | | |
| | C-5 | | | | | | | | |
| Sensitizer | D-1 | 0.002 | 1.2 | 0.1 | 0.1 | 0.1 | 0.1 | 0.1 | 0.1 |
| | D-2 | | | | | | | | |
| | D-3 | | | | | | | | |
| | D-4 | | | | | | | | |
| | D-5 | | | | | | | | |
| | D-6 | | | | | | | | |
| | D-7 | | | | | | | | |
| | D-8 | | | | | | | | |
| | D-9 | | | | | | | | |
| | D-10 | | | | | | | | |
| | D-11 | | | | | | | | |
| | D-12 | | | | | | | | |
| | D-13 | | | | | | | | |
| | D-14 | | | | | | | | |
| | D-15 | | | | | | | | |

| | | | | | | | | |
|---|---|---|---|---|---|---|---|---|
| Viscosity: mPa · s | 7.2 | 6.8 | 7.1 | 7.2 | 7.2 | 7.2 | 7.2 | 9.1 |
| Surface tension: mN/m | 34.1 | 34 | 34 | 33.5 | 34.6 | 34.8 | 34.6 | 34.9 |
| Evaluation of collapse defects | A | B | B | B | B | B | B | A |
| (condition A) | | | | | | | | |
| Evaluation of collapse defects | B | B | B | B | B | B | B | A |
| (condition B) | | | | | | | | |
| Evaluation of reaction speed | B | B | C | C | C | C | C | A |
| Evaluation of filling | A | A | A | A | A | A | A | B |
| properties | | | | | | | | |
| Evaluation of releasability | A | B | A | B | C | A | A | B |

TABLE 6

| | | Example | Example | Example | Example | Example | Example | Example | Example |
|---|---|---|---|---|---|---|---|---|---|
| | | 17 | 18 | 19 | 20 | 21 | 22 | 23 | 24 |
| Polymerizable | A-1 | 38 | | 53 | | | 45 | | |
| compound | A-2 | | | | | | | 48 | |
| | A-3 | 20 | 63 | | 78 | | 33 | | 33 |
| | A-4 | | | | | | | | 48 |
| | A-5 | | | | | | | | |
| | A-6 | | 15 | | | | | 38 | |
| | A-7 | | | | | | | 10 | |
| | A-8 | 35 | | 20 | 10 | | 15 | | 13 |
| | A-9 | | 15 | | | 79 | | | |
| | A-10 | | | 20 | | | | | |
| | A-11 | | | | 5 | 15 | | | |
| Photopolymerization | B-1 | 2 | 2 | 2 | 2 | | 2 | | |
| initiator | B-2 | | | | | 2 | | 2.6 | |
| | B-3 | | | | | | | | 2.3 |
| | B-4 | | | | | | | | |
| | B-5 | | | | | | | | |
| | B-6 | 1.9 | 1.9 | 1.9 | 1.9 | | 1.99 | | |
| | B-7 | | | | | | | | |
| | B-8 | | | | | 0.9 | | | |
| Release agent | C-1 | 3 | 3 | 3 | 3 | | | | |
| | C-2 | | | | | 3 | 3 | 1 | |
| | C-3 | | | | | | | | 3 |
| | C-4 | | | | | | | | |
| | C-5 | | | | | | | | |
| Sensitizer | D-1 | 0.1 | 0.1 | 0.1 | 0.1 | 0.1 | 0.01 | 0.4 | 0.7 |
| | D-2 | | | | | | | | |
| | D-3 | | | | | | | | |
| | D-4 | | | | | | | | |
| | D-5 | | | | | | | | |
| | D-6 | | | | | | | | |
| | D-7 | | | | | | | | |
| | D-8 | | | | | | | | |
| | D-9 | | | | | | | | |
| | D-10 | | | | | | | | |
| | D-11 | | | | | | | | |
| | D-12 | | | | | | | | |
| | D-13 | | | | | | | | |
| | D-14 | | | | | | | | |
| | D-15 | | | | | | | | |

| | | | | | | | | |
|---|---|---|---|---|---|---|---|---|
| Viscosity: mPa · s | 5.8 | 40 | 205 | 59 | 490 | 5.9 | 5.8 | 9.6 |
| Surface tension: mN/m | 32.1 | 36.4 | 36.6 | 33.9 | 36.9 | 34.1 | 31.3 | 34.4 |
| Evaluation of collapse defects | A | B | A | A | B | A | A | A |
| (condition A) | | | | | | | | |
| Evaluation of collapse defects | B | B | B | B | B | A | A | A |
| (condition B) | | | | | | | | |
| Evaluation of reaction speed | A | C | C | C | C | A | A | A |
| Evaluation of filling | A | B | D | C | D | A | A | A |
| properties | | | | | | | | |
| Evaluation of releasability | A | B | C | A | A | A | A | A |

TABLE 7

| | | Example | Example | Example | Example | Example | Comparative | Comparative | Comparative |
|---|---|---|---|---|---|---|---|---|---|
| | | 25 | 26 | 27 | 28 | 29 | Example 1 | Example 2 | Example 3 |
| Polymerizable | A-1 | 60 | 40 | | 40 | 60 | 60 | | |
| compound | A-2 | | | 15 | | 8 | | 47 | |
| | A-3 | 22 | 24 | 60 | 40 | | 20 | | 40 |
| | A-4 | | | | | | | | 40 |
| | A-5 | | 10 | | | | | | |
| | A-6 | | | | | | | 38 | |
| | A-7 | | | 5 | | | | 8 | |
| | A-8 | 9 | 20 | 14 | 13 | 25 | 13 | | 14 |
| | A-9 | | | | | | | | |
| | A-10 | | | | | | | | |
| | A-11 | | | | | | | | |
| Photopolymerization | B-1 | | | 4.7 | | | 2 | | |
| initiator | B-2 | | | | 2 | | | 2 | |
| | B-3 | | | | | 3 | | | 2 |
| | B-4 | 2 | | | | | | | |
| | B-5 | | 2.95 | | | | | | |
| | B-6 | 1.7 | | | | | 1.9 | 1 | 0.5 |
| | B-7 | | | | | | | | |
| | B-8 | | | | 1.2 | 0.8 | | | |
| Release agent | C-1 | | 3 | | 3 | | 3 | | |
| | C-2 | 5 | | | | | | 3 | |
| | C-3 | | | | | 3 | | | 3 |
| | C-4 | | | | | | | | |
| | C-5 | | | 1 | | | | | |
| Sensitizer | D-1 | | | | | 0.1 | | | |
| | D-2 | 0.3 | | | | | | | |
| | D-3 | | 0.05 | | | | | | |
| | D-4 | | | 0.3 | | | | | |
| | D-5 | | | | 0.8 | 0.1 | | | |
| | D-6 | | | | | | | | |
| | D-7 | | | | | | | | |
| | D-8 | | | | | | | | |
| | D-9 | | | | | | | | |
| | D-10 | | | | | | | | |
| | D-11 | | | | | | 0.1 | | |
| | D-12 | | | | | | | 1 | |
| | D-13 | | | | | | | | 0.5 |
| | D-14 | | | | | | | | |
| | D-15 | | | | | | | | |

| | | | | | | | | |
|---|---|---|---|---|---|---|---|---|
| Viscosity: mPa · s | 7.8 | 9.8 | 6.5 | 5.6 | 7.1 | 7.2 | 5.9 | 10.1 |
| Surface tension: mN/m | 34.9 | 33.8 | 31.9 | 34 | 33.1 | 34 | 30.9 | 34 |
| Evaluation of collapse defects | A | A | A | A | A | B | B | B |
| (condition A) | | | | | | | | |
| Evaluation of collapse defects | A | A | A | A | A | D | D | D |
| (condition B) | | | | | | | | |
| Evaluation of reaction speed | A | A | A | A | A | D | D | D |
| Evaluation of filling | A | A | A | A | A | A | B | B |
| properties | | | | | | | | |
| Evaluation of releasability | A | A | A | A | A | B | B | A |

TABLE 8

| | | Comparative | Comparative | Comparative | Comparative | Comparative | Comparative | Comparative | Comparative |
|---|---|---|---|---|---|---|---|---|---|
| | | Example 4 | Example 5 | Example 6 | Example 7 | Example 8 | Example 9 | Example 10 | Example 11 |
| Polymerizable | A-1 | 30 | 47 | 60 | | 40 | | 60 | 60 |
| compound | A-2 | | | | 46 | 30 | | | |
| | A-3 | 30 | 34 | 20 | | | | 20 | 20 |
| | A-4 | | | | | | | | |
| | A-5 | 20 | | | | | | | |
| | A-6 | 14 | | | 30 | | | | |
| | A-7 | | | | 18 | | | | |
| | A-8 | | 13 | 13 | | 22 | | 13 | 13 |
| | A-9 | | | | | | 79 | | |
| | A-10 | | | | | | | | |
| | A-11 | | | | | | 15 | | |
| Photopolymerization | B-1 | 2 | | 2 | | | | 2 | 2 |
| initiator | B-2 | | 2 | | | 5 | | | |
| | B-3 | | | | | | | | |
| | B-4 | | | | 3 | | | | |
| | B-5 | | | | | | | | |
| | B-6 | 0.5 | 0.5 | 2 | | | | 1.9 | 1.9 |
| | B-7 | | | | | | | | |
| | B-8 | | | | | | 3 | | |
| Release agent | C-1 | | | | 3 | | | 3 | 3 |
| | C-2 | | | 3 | | | | | |
| | C-3 | | | | | 3 | | | |
| | C-4 | 3 | | | | | 3 | | |
| | C-5 | | 3 | | | | | | |
| Sensitizer | D-1 | | | | | | | | |
| | D-2 | | | | | | | | |
| | D-3 | | | | | | | | |
| | D-4 | | | | | | | | |
| | D-5 | | | | | | | | |
| | D-6 | | | | | | | | |
| | D-7 | | | | | | | | |
| | D-8 | | | | | | | | |
| | D-9 | | | | | | | | |
| | D-10 | | | | | | | | |
| | D-11 | 0.5 | | | | | | | |
| | D-12 | | 0.5 | | | | | | |
| | D-13 | | | | | | | | |
| | D-14 | | | | | | | 0.1 | |
| | D-15 | | | | | | | | 0.1 |

| | | | | | | | | |
|---|---|---|---|---|---|---|---|---|
| Viscosity: mPa · s | 22.1 | 6 | 7 | 6.3 | 6.5 | 488 | 7.2 | 7.2 |
| Surface tension: mN/m | 35.8 | 28.3 | 34 | 30.9 | 33.1 | 37.8 | 34 | 34 |
| Evaluation of collapse defects | B | B | B | B | C | B | B | B |
| (condition A) | | | | | | | | |
| Evaluation of collapse defects | D | D | C | C | C | D | D | D |
| (condition B) | | | | | | | | |
| Evaluation of reaction speed | D | D | C | C | C | D | D | D |
| Evaluation of filling | B | B | A | A | A | D | A | A |
| properties | | | | | | | | |
| Evaluation of releasability | B | A | A | A | B | C | B | B |

<Raw Materials>

The specifications of respective raw materials are as follows.

<<Polymerizable Compound>>

A-1: Compound having the following structure (molecular weight of 246).

A-2: Neopentylglycol diacrylate (molecular weight of 212).

A-3: Compound having the following structure (molecular weight of 196).

A-4: Phenylethylene glycol diacrylate (molecular weight of 246).

A-5: 2-Phenylpropane-1,3-diyl diacrylate (molecular weight of 260).

A-6: Benzyl acrylate (molecular weight of 162).

A-7: Isobornyl acrylate (molecular weight of 208).

A-8: Compound having the following structure (molecular weight of 240).

A-9: Pentaerythritol tetraacrylate (molecular weight of 352).

A-10: Bisphenol A EO-modified diacrylate (molecular weight of 777, m+n=10).

A-11: Polyester acrylate (PHOTOMER 5018, produced by SAN NOPCO LIMITED, molecular weight of 1,100).

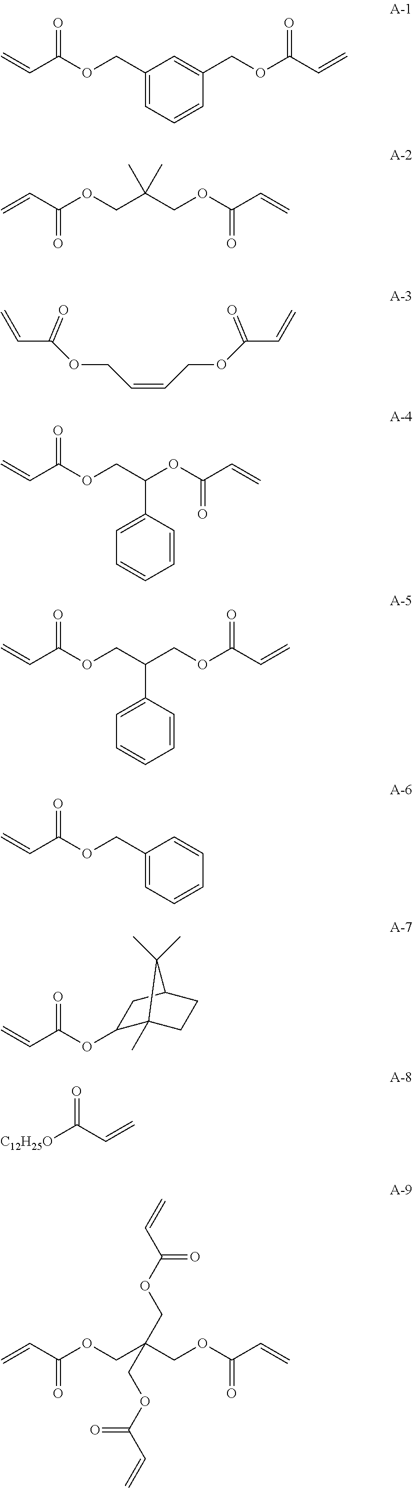

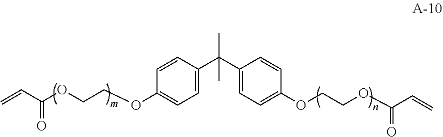

<<Photopolymerization Initiator>>

B-1: Compound having the following structure (Irgacure 819, produced by BASF SE).

B-2: Compound having the following structure (Irgacure TPO, produced by BASF SE).

B-3: Compound having the following structure (Irgacure TPO-L, produced by BASF SE).

B-4: Compound having the following structure (Irgacure OXE01, produced by BASF SE).

B-5: Oxime ester-based compound (Irgacure OXE04, produced by BASF SE).

B-6: Compound having the following structure (DAROCUR 1173, produced by Ciba Specialty Chemicals Inc.).

B-7: Compound having the following structure (Irgacure 379EG, produced by BASF SE).

B-8: Compound having the following structure (Irgacure 907, produced by BASF SE).

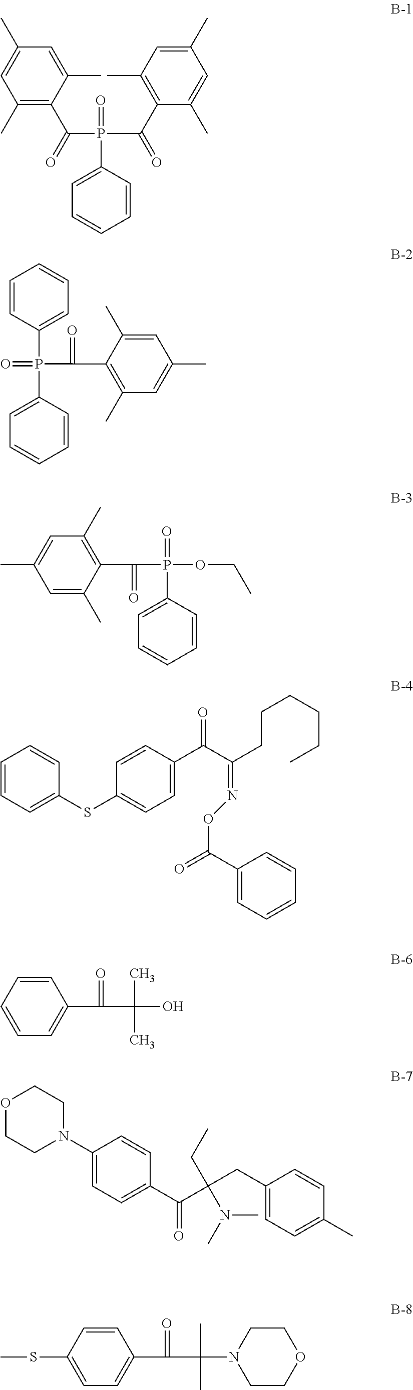

<<Release Agent>>

C-1 to C-5: Compounds having the following respective structures.

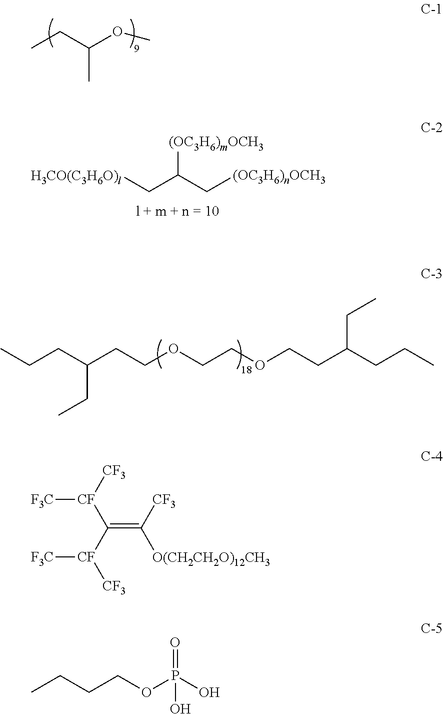

<<Sensitizer>>

D-1 to D-10: Compounds having the following respective structures

D-11: Dibutoxyanthracene

D-12: 4,4′-Bis(diethylamino)benzophenone

D-13: 2-Isopropyl thioxanthone

D-14: Methylene blue

D-15: Phenothiazine

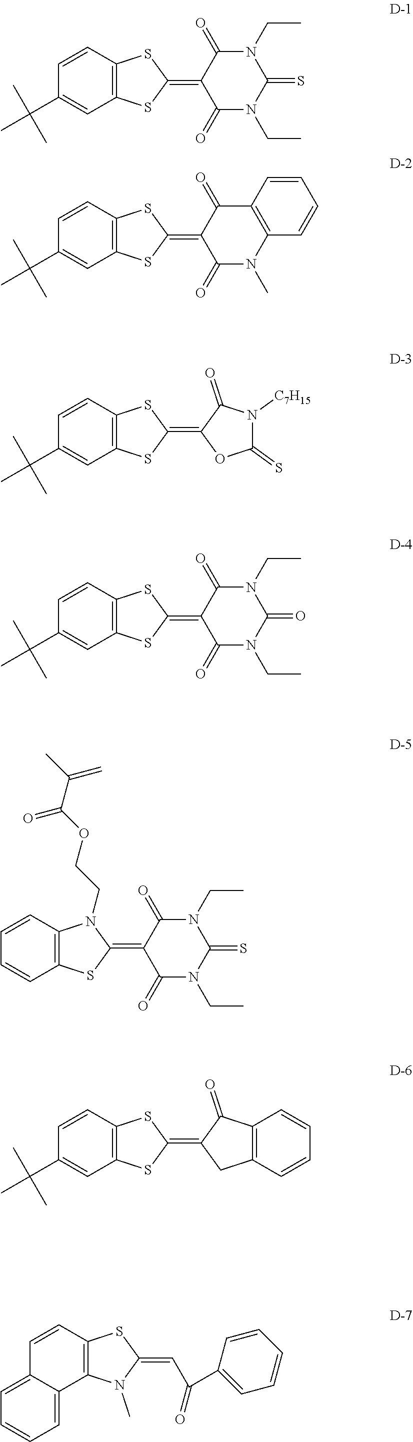

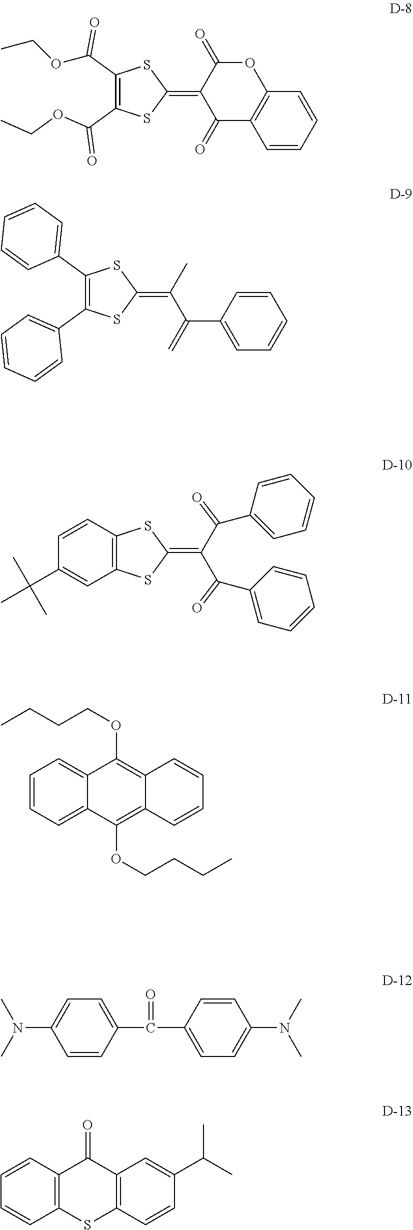

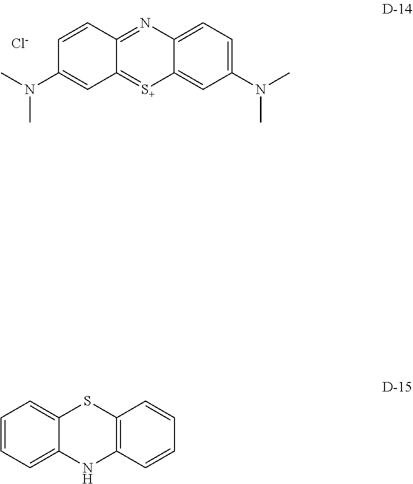

<Evaluation>

For each composition for forming a pattern of Examples and Comparative Examples, the following items were evaluated. Moreover, the illuminance of the ultra-high pressure mercury lamp was measured using ACCUMULATED UV METER UIT-250 manufactured by Ushio Inc.

<<Evaluation of Suppression of Pattern Collapse Defects (Resolution)>>

A silicon wafer was spin-coated with the composition for forming a closely adhesive layer shown in Example 6 of JP2014-024322A, and heated for 1 minute using a hot plate at 220° C. to form a closely adhesive layer having a thickness of 5 nm. Moreover, the composition for forming a pattern was applied onto the closely adhesive layer using an ink jet device (INK JET PRINTER DMP-2831 manufactured by FUJIFILM Dimatix Inc.). Thereafter, a mold for imprinting was pressed against the silicon wafer from the side of the composition for forming a pattern under a helium atmosphere. The used mold is a quartz mold with line/space having a line width of 15 nm, a depth of 40 nm, and a pitch of 30 nm. Subsequently, exposure was performed from the surface of the mold using an ultra-high pressure mercury lamp under the following two kinds of conditions, and the mold was released to obtain a pattern consisting of a cured substance of the composition for forming a pattern.

TABLE 9

| | Illuminance [mW/cm²] at each wavelength | | | Exposure time |
|---|---|---|---|---|
| | 313 nm | 365 nm | 405 nm | (sec) |
| Condition A | 500 | 680 | 570 | 0.2 |
| Condition B | 1000 | 1350 | 1150 | 0.1 |

Using a defect review classifying device (RS-5500 manufactured by Hitachi High-Tech Fielding Corporation), scanning electron microscope (SEM) observation was performed at 500 places in the line/space area of the pattern consisting of the cured substance. Moreover, a rate (defect generation rate) R (%) at which pattern collapse defects were generated was derived by the following expression, and a degree (goodness of resolution) of the suppression of the pattern collapse defects was evaluated as follows according to the value.
Defect generation rate R(%)=[total number of places where pattern collapse was observed as result of SEM observation]/[total number (500 in case of present example) of places where SEM observation was performed]×100
A: R=0 (that is, collapse defects were not observed and the resolution was good.)
B: 0%<R≤1%
C: 1%<R≤10%
D: 10%<R

<<Evaluation of Reaction Speed>>

Using FT-IR (Nicolet iS50R manufactured by Thermo Fisher Scientific Inc.) having a RapidScan function, the reaction speed of the curing of the composition for forming a pattern was measured through attenuated total reflection (ATR). 1 μL of the composition for forming a pattern was added dropwise onto a diamond-made prism, and slide glass was overlaid on the prism from above the composition for forming a pattern. Subsequently, the composition for forming a pattern was exposed to ultraviolet rays using an ultra-high pressure mercury lamp.

Moreover, in the exposure, for the polymerizable group of the polymerizable compound in the composition for forming a pattern, the reaction rate at 0.5 seconds after the exposure was measured using the FT-IR device. Exposure conditions, and conditions for the measurement by the FT-IR device were as follows. Furthermore, the reaction rate was defined by the following expression while focusing on a decrease in an infrared absorption peak (near 1,630 cm⁻¹) due to C═C stretching vibration of a vinyl group. In the following expression, a “peak surface area” indicates a “peak surface area” of an FT-IR spectrum in a range of 1,650 to 1,600 cm⁻¹.
Reaction rate(%)=[(peak surface area before exposure)−(peak surface area at 0.5 seconds after exposure)]/[peak surface area before exposure]×100
Exposure conditions

TABLE 10

| Illuminance [mW/cm²] at each wavelength | | | Exposure time |
|---|---|---|---|
| 313 nm | 365 nm | 405 nm | (sec) |
| 100 | 135 | 115 | 1 |

Conditions for measurement by FT-IR device
   Measured wave number range: 3,500 to 400 cm⁻¹
   Wave number resolution: 32 cm⁻¹
   Number of times of high-speed scan: 100 spectra/sec

Furthermore, the reaction speed was evaluated as follows according to the reaction rate.
A: 85%≤Reaction rate
B: 75%≤Reaction rate<85%
C: 70%≤Reaction rate<75%
D: Reaction rate<70%

<<Evaluation of Filling Properties>>

In the same manner as in the case of the evaluation of the suppression of the collapse defects, a closely adhesive layer was formed on a silicon wafer, the composition for forming a pattern was applied onto the closely adhesive layer, and a mold for imprinting was pressed against the silicon wafer from the side of the composition for forming a pattern. However, the used mold is a quartz mold having a concave-type pillar structure in which an opening portion is a circle with a radius of 1 μm and the depth is 2 μm.

The state of filling the inside of the concave part of the mold with the composition for forming a pattern was observed with a camera, and a time required to complete the filling was measured. Moreover, the filling properties were evaluated as follows according to the time.
A: Shorter than 3 seconds
B: 3 seconds or longer and shorter than 5 seconds
C: 5 seconds or longer and shorter than 10 seconds
D: 10 seconds or longer

<<Evaluation of Releasability>>

A silicon wafer was spin-coated with the composition for forming a closely adhesive layer shown in Example 6 of JP2014-024322A, and heated for 1 minute using a hot plate at 220° C. to form a closely adhesive layer having a thickness of 5 nm. Moreover, the composition for forming a pattern was applied onto the closely adhesive layer using an ink jet device (INK JET PRINTER DMP-2831 manufactured by FUJIFILM Dimatix Inc.). Thereafter, a mold for imprinting was pressed against the silicon wafer from the side of the composition for forming a pattern under a helium atmosphere. The used mold is a quartz mold with line/space having a line width of 20 nm, a depth of 50 nm, and a pitch of 40 nm. Subsequently, exposure was performed from the surface of the mold using an ultra-high pressure mercury lamp under a condition of an exposure amount of 100 mJ/cm², and the mold was released to obtain a pattern consisting of a cured substance of the composition for forming a pattern.

In the pattern formation, a force (releasing force F, unit: N) required for release in a case where the quartz mold was released from the pattern was measured, and the releasability was evaluated as follows according to the measured value. The releasing force was measured according to the method of Comparative Example described in paragraphs 0102 to 0107 of JP2011-206977A.
A: F≤15 N
B: 15 N<F≤18N
C: 18 N<F≤20N

<Evaluation Result>

The evaluation results of the respective Examples and Comparative Examples are shown in Tables 4 to 8. From the results, it was found that by using the composition for forming a pattern according to the embodiment of the present invention, an imprinting method, in which pattern collapse defects are suppressed, can be performed even in a case where short-time exposure to ultraviolet rays is performed in consideration of a throughput.

In addition, a predetermined pattern corresponding to a semiconductor circuit was formed on the silicon wafer by using the composition for forming a pattern according to each of Examples. Moreover, each silicon wafer was dry-etched by using this pattern as an etching mask, and each semiconductor element was produced using this silicon wafer. There was no problem with the performance of any of the semiconductor elements.

What is claimed is:

1. A composition for forming a pattern for imprinting, comprising:
a polymerizable compound;
a photopolymerization initiator; and
a sensitizer containing two or more of at least one kind of atom selected from the group consisting of a nitrogen atom and a sulfur atom,
wherein a length of a specific atom chain from one atom to another atom among the two or more atoms is 2 or 3 in terms of the number of atoms.

2. The composition for forming a pattern according to claim 1,
wherein the specific atom chain is included in a ring structure.

3. The composition for forming a pattern according to claim 1,
wherein the length of the specific atom chain is 3 in terms of the number of atoms.

4. The composition for forming a pattern according to claim 1,
wherein a compound represented by Formula (PS-1) is contained as the sensitizer, 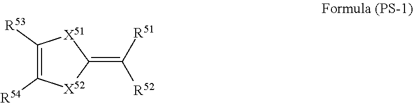
in Formula (PS-1),
X⁵¹ and X⁵² each independently represent —S— or —NR⁵⁵—, and R⁵⁵ represents a hydrogen atom or a monovalent substituent, and
R⁵¹ to R⁵⁴ each independently represent a hydrogen atom or a monovalent substituent, R⁵¹ and R⁵² may be bonded to each other to form a ring, and R⁵³ and R⁵⁴ may be bonded to each other to form a ring.

5. The composition for forming a pattern according to claim 4,
wherein at least one of R⁵¹, . . . , or R⁵⁴ has a π-conjugated linking group adjacent to a carbon atom to which at least one of R⁵¹, . . . , or R⁵⁴ is bonded.

6. The composition for forming a pattern according to claim 5,
wherein at least three of R⁵¹, . . . , or R⁵⁴ have a π-conjugated linking group adjacent to a carbon atom to which each of at least three of R⁵¹, . . . , or R⁵⁴ is bonded.

7. The composition for forming a pattern according to claim 5,
wherein the π-conjugated linking group is a linking group, which consists of one selected from the group consisting of —CR⁶⁰═CR⁶¹—, —CR⁶²═N—, —NR⁶³—, —O—, —C(═O)—, —S—, and —C(═S)—, or a combination of two or more thereof,
where R⁶⁰ to R⁶³ each independently represent a hydrogen atom or a monovalent substituent, and R⁶⁰ and R⁶¹ may be bonded to each other to form a ring.

8. The composition for forming a pattern according to claim 1,
wherein a compound represented by Formula (PS-2) is contained as the sensitizer, 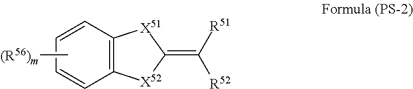
in Formula (PS-2),
X⁵¹ and X⁵² each independently represent —S— or —NR⁵⁵—, and R⁵⁵ represents a hydrogen atom or a monovalent substituent,
R⁵¹ and R⁵² each independently represent a hydrogen atom or a monovalent substituent, and may be bonded to each other to form a ring,
R⁵⁶ represents a monovalent substituent, and
m represents an integer of 0 to 4.

9. The composition for forming a pattern according to claim 8,
wherein a compound represented by Formula (PS-3) is contained as the sensitizer, 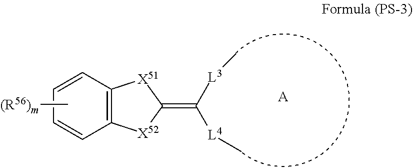
in Formula (PS-3),
X⁵¹, X⁵², R⁵⁶, and m have the same definitions as X⁵¹, X⁵², R⁵⁶, and m in Formula (PS-2), respectively,
L³ and L⁴ are each independently a divalent linking group, and at least one of L³ or L⁴ is a π-conjugated linking group, and
A represents a ring structure including L³ and L⁴.

10. The composition for forming a pattern according to claim 9,
wherein the entire ring structure A is a π-conjugated linking group which links two bonding sites of a carbon atom to which the ring structure A is bonded.

11. The composition for forming a pattern according to claim 9,
wherein the π-conjugated linking group in the ring structure A is a linking group, which consists of one selected from the group consisting of —CR⁶⁰═CR⁶¹—, —CR⁶²═N—, —NR⁶³—, —O—, —C(═O)—, —S—, and —C(═S)—, or a combination of two or more thereof,
where, in formulae, R⁶⁰ to R⁶³ each independently represent a hydrogen atom or a monovalent substituent, and R⁶⁰ and R⁶¹ may be bonded to each other to form a ring.

12. The composition for forming a pattern according to claim 11,
wherein the π-conjugated linking group in the ring structure A includes at least one of —NR⁶³— or —C(═O)—.

13. The composition for forming a pattern according to claim 9,
wherein the ring structure A is a 5- to 7-membered ring.

14. The composition for forming a pattern according to claim 8,
wherein a compound represented by Formula (PS-3a) or Formula (PS-3b) is contained as the sensitizer, 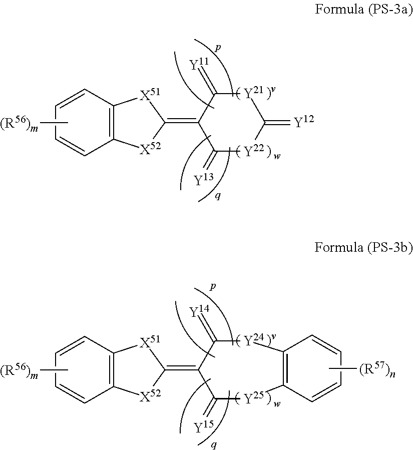
in Formula (PS-3a) and Formula (PS-3b),
X⁵¹, X⁵², R⁵⁶, and m have the same definitions as X⁵¹, X⁵², R⁵⁶, and m in Formula (PS-2), respectively,
Y¹¹, Y¹², Y¹³, Y¹⁴, and Y¹⁵ are each independently an oxygen atom or a sulfur atom,
Y²¹, Y²², Y²⁴, and Y²⁵ are each independently —CR⁷⁰R⁷¹—, —O—, —NR⁷²—, or —S—, and R⁷⁰ to R⁷² each represent a hydrogen atom or a monovalent substituent,
R⁵⁷ represents a monovalent substituent, and n represents an integer of 0 to 4,
p and q are each 0 or 1, and p+q satisfies 1 or 2,
v and w are each 0 or 1, and v+w satisfies 1 or 2, and
p+q+v+w in Formula (PS-3a) is 3 or 4, and p+q+v+w in Formula (PS-3b) is 2 or 3.

15. The composition for forming a pattern according to claim 4,
wherein both X⁵¹ and X⁵² are —S—.

16. The composition for forming a pattern according to claim 4,
wherein among X⁵¹ and X⁵², one is —NR⁵⁵— and the other is —S—.

17. The composition for forming a pattern according to claim 1,
wherein a content of the sensitizer is 0.001% to 3% by mass with respect to an amount of a total solid content.

18. The composition for forming a pattern according to claim 1,
wherein Cs/Ci, which is a mass ratio of a content Cs of the sensitizer to a content Ci of the photopolymerization initiator, is 0.0005 to 0.3.

19. The composition for forming a pattern according to claim 1,
wherein at least one kind of an acylphosphine-based compound or an oxime ester-based compound is contained as the photopolymerization initiator.

20. The composition for forming a pattern according to claim 1,
wherein the polymerizable compound includes a monofunctional polymerizable compound and a polyfunctional polymerizable compound, and
a content of the monofunctional polymerizable compound in a total polymerizable compound is 5% to 30% by mass.

21. The composition for forming a pattern according to claim 1,
wherein a viscosity of the composition for forming a pattern at 23° C. is 50 mPa·s or lower.

22. The composition for forming a pattern according to claim 1, further comprising a release agent.

23. The composition for forming a pattern according to claim 1,
wherein a content of a solvent is 5% by mass or less with respect to the composition for forming a pattern.

24. A kit comprising a combination of the composition for forming a pattern according to claim 1 and a composition for forming an underlayer film, which is for forming an underlayer film for imprinting.

25. A cured film which is formed of the composition for forming a pattern according to claim 1.

26. A laminate comprising:
a layered film consisting of the composition for forming a pattern according to claim 1; and
a substrate supporting the layered film.

27. A pattern producing method comprising applying the composition for forming a pattern according to claim 1 onto a substrate or a mold and irradiating the composition for forming a pattern with light in a state of being sandwiched between the mold and the substrate.

28. A method for manufacturing a semiconductor element, comprising the producing method according to claim 27 as a step.

29. The method for manufacturing a semiconductor element according to claim 28, further comprising etching the substrate using, as a mask, the pattern obtained by the producing method.
